(19) United States
(12) Patent Application Publication
(10) Pub. No.: US 2026/0068076 A1
(43) Pub. Date: Mar. 5, 2026

(54) VLC SYSTEM WITH ENHANCED COOLING FEATURES

(71) Applicant: Cisco Technology, Inc., San Jose, CA (US)

(72) Inventors: Joseph F. JACQUES, Austin, TX (US); Sung W. MOON, Woodbury, MN (US); Albert W. CHAN, San Jose, CA (US); Mark C. NOWELL, Ottawa (CA); Joel R. GOERGEN, Soulsbyville, CA (US)

(21) Appl. No.: 19/040,696

(22) Filed: Jan. 29, 2025

Related U.S. Application Data
(60) Provisional application No. 63/688,095, filed on Aug. 28, 2024.

(51) Int. Cl. H05K 7/20; H01L 23/467; H05K 7/14

(52) U.S. Cl. CPC H05K 7/20145; H05K 7/1424

(57) ABSTRACT

A vertical line card (VLC) system is disclosed. In one aspect, a VLC system includes a vertically-oriented printed circuit board (PCB), a vertically-oriented integrated circuit (IC) mounted to the PCB, and a cage assembly having cages arranged in a splayed layout so that the cages angularly fan out with respect to the IC.

### CROSS-REFERENCE TO RELATED APPLICATIONS

This application claims the benefit of co-pending U.S. provisional patent application Ser. No. 63/688,095 filed Aug. 28, 2024. The aforementioned related patent application is herein incorporated by reference in its entirety.

### TECHNICAL FIELD

Embodiments presented in this disclosure generally relate to vertical line card (VLC) systems. More specifically, embodiments disclosed herein relate to VLC systems having enhanced cooling features.

### BACKGROUND

A vertical line card (VLC) system has its main printed circuit board (PCB) oriented vertically within a chassis, rather than horizontally. Optical devices and an integrated circuit (IC), such as a switching/routing application-specific circuit (ASIC), can be mounted to the vertically-oriented PCB. During operation, an air flow is directed through the system from the front of the chassis out the back. The vertically-oriented PCB can cause blockage of rearward air flow without the presence of notches or cutouts in the PCB. Since ventilation notches or cutouts in the main PCB are at the expense of area available for component placement and routing traces, there is typically a design trade-off between high speed electrical routing and thermal design of the VLC system. Striking a balance between these design considerations has presented certain challenges.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1 is a perspective view of a vertical line card (VLC) system according to one or more embodiments of the present disclosure.

FIG. 2A is a front view of an assembly for a VLC system, showing a cage assembly arranged relative to a vertically-oriented printed circuit board (PCB) having an integrated circuit (IC) mounted thereto, according to one or more embodiments of the present disclosure.

FIG. 2B is a front, perspective view of the assembly of FIG. 2A.

FIG. 2C is a rear, perspective view of the assembly of FIG. 2A.

FIG. 2D is a front view of the assembly of FIG. 2A with cages of the assembly shown transparent for illustrative purposes.

FIG. 2E is a front view of an assembly for a VLC system, showing a cage assembly arranged relative to a vertically-oriented PCB having an IC mounted thereto, according to one or more embodiments of the present disclosure.

FIG. 2F is a front view of an assembly for a VLC system, showing a cage assembly arranged relative to a vertically-oriented PCB having an IC mounted thereto, according to one or more embodiments of the present disclosure.

FIG. 3A is a perspective view of an assembly for a VLC system, showing a cage assembly having cages arranged relative to a vertically-oriented PCB, according to one or more embodiments of the present disclosure.

FIG. 3B is a perspective view of the cage assembly of FIG. 3A.

FIG. 4 is a close-up, front view of fluid flow between cages of a cage assembly for a VLC system, according to one or more embodiments of the present disclosure.

FIG. 5 is a perspective view of a cage assembly having mounting and cooling features, according to one or more embodiments of the present disclosure.

FIG. 6 is a front view of an assembly for a VLC system, according to one or more embodiments of the present disclosure.

FIGS. 7A and 7B depict a cage assembly for a VLC system, according to one or more embodiments of the present disclosure.

FIGS. 8A and 8B depict a cage assembly for a VLC system, according to one or more embodiments of the present disclosure.

FIG. 9 depicts a front view of an assembly for a VLC system, according to one or more embodiments of the present disclosure.

FIG. 10 depicts a front view of an assembly for a VLC system, according to one or more embodiments of the present disclosure.

FIGS. 11A, 11B, 11C, 11D, and 11E depict various PCB cage hole arrangements that can be implemented in a VLC system, according to one or more embodiments of the present disclosure.

FIG. 12 is a front view of an assembly for a VLC system, according to one or more embodiments of the present disclosure.

FIG. 13 is a front view of an assembly for a VLC system, according to one or more embodiments of the present disclosure.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

In one aspect, a system is provided. The system includes a vertically-oriented printed circuit board (PCB); a vertically-oriented integrated circuit (IC) mounted to the PCB; and a cage assembly having cages arranged in a splayed layout so that the cages angularly fan out with respect to the IC.

In another aspect, in combination with any example system above or below, the system defines a vertical direction, a longitudinal direction, and a lateral direction mutually perpendicular to one another, and wherein the cages are arranged in the splayed layout so that a width axis of each one of the cages is angled with respect to the lateral direction.

In another aspect, in combination with any example system above or below, the cages are arranged in the splayed layout in at least one column, and wherein angles of the cages of the at least one column, with respect to the lateral direction, increase in increments from one row of cages of the at least one column to the next.

In another aspect, in combination with any example system above or below, the cages are arranged in the splayed layout in at least two columns, including a first column and a second column arranged outward of the first column with respect to the IC, and wherein angles of the cages of the first column, with respect to the lateral direction, increase in first increments from one row of cages of the first column to the next, and wherein angles of the cages of the second column, with respect to the lateral direction, increase in second increments from one row of cages of the second column to the next, and wherein the second increments are greater than the first increments.

In another aspect, in combination with any example system above or below, the cages are arranged in the splayed layout so that a first set of the cages is arranged above a fan out plane and a second set of the cages is arranged below the fan out plane, and wherein the cages of the first set are angled with a positive angle with respect to the fan out plane and the cages of the second set are angled with a negative angle with respect to the fan out plane.

In another aspect, in combination with any example system above or below, each one of the cages has an inner end and an outer end, and wherein the cages are arranged in the splayed layout so that, for a given cage of the cages, the inner end of the given cage is arranged closer to the fan out plane than the outer end of the given cage.

In another aspect, in combination with any example system above or below, the cages are arranged in the splayed layout so that flow channels defined between rows of the cages progressively increase in cross-sectional area as the flow channels extend away from the IC.

In another aspect, in combination with any example system above or below, the vertically-oriented PCB defines a plurality of holes, including cage holes and drain holes, with the cage holes being aligned with respective ones of the cages along a primary airflow direction and the drain holes not being aligned with the cages along the primary airflow direction.

In another aspect, in combination with any example system above or below, the vertically-oriented PCB defines the plurality of cage holes so that, for at least one row of the plurality of holes, the cage holes of the at least one row decrease in size the closer the cage holes of the at least one row are to the drain hole of the at least one row.

In another aspect, in combination with any example system above or below, the vertically-oriented PCB defines the plurality of cage holes so that, for at least one row of the plurality of holes, the cage holes of the at least one row alternate between pairs of small cage holes and large cage holes.

In another aspect, in combination with any example system above or below, the vertically-oriented PCB defines the plurality of cage holes so that, for a second row of the plurality of holes that is positioned adjacent the at least one row of the plurality of holes, the cage holes of the second row alternate between pairs of small cage holes and large cage holes, and wherein the alternating pattern of the at least one row is staggered with respect to the alternating pattern of the second row.

In another aspect, in combination with any example system above or below, the cages include cage vents at their respective rear portions that allow air to escape the cages and flow to the drain holes.

In another aspect, in combination with any example system above or below, the cages each include a top wall, a bottom wall, and opposing sidewalls, and wherein the cage vent of at least one cage of the cages is defined by the top wall, the bottom wall, and the opposing sidewalls of the at least one cage.

In another aspect, in combination with any example system above or below, air escaping the cages through the cage vents flows laterally to the drain holes by way of flow channels defined between the cages.

In one aspect, a system is provided. The system includes a vertically-oriented printed circuit board (PCB) defining cage holes and drain holes; a vertically-oriented integrated circuit (IC) mounted to the PCB; and a cage assembly having cages arranged in a splayed layout so that the cages angularly fan out with respect to the IC and define flow channels therebetween, wherein the cages align with the cage holes along a primary airflow direction and have cage vents that allow air to escape the cages and flow by way of the flow channels to the drain holes.

In another aspect, in combination with any example system above or below, the cages are arranged in the splayed layout so that flow channels defined between rows of the cages progressively increase in cross-sectional area as the flow channels extend away from the IC.

In one aspect, a system is provided. The system includes a vertically-oriented printed circuit board (PCB) defining a slot and a plurality of cage holes; a vertically-oriented integrated circuit (IC) mounted to the PCB above the slot; and a cage assembly having a cage frame supporting a plurality of cages and having a front and a back spaced from one another along a first direction, the cage frame defines slots each having a long axis extending along the first direction and aligned with walls of the cages.

In another aspect, in combination with any example system above or below, the cage frame has a top frame wall and a side frame wall, and wherein the top frame wall, the side frame wall, or both, define at least one of the slots.

In another aspect, in combination with any example system above or below, the cage frame defines at least one frame vent arranged at the back of and aligned with at least one of the plurality of cages.

In another aspect, in combination with any example system above or below, the cage assembly has a forward stiffener flange arranged to couple with a forward faceplate of a chassis of a system; a plurality of tabs arranged at the back and being vertically spaced from one another, and wherein the tabs are arranged to couple with a vertically-oriented printed circuit board; and standoff bars extending between and coupling the forward stiffener flange and respective ones of the plurality of tabs.

In one aspect, a system is provided. The system includes a vertically-oriented printed circuit board (PCB); and a cage assembly having cages each arranged to receive an optical module, and wherein at least two cages of the cages each have a riding heat sink that includes a fin array, wherein the at least two cages are arranged so that the fin arrays are nested in a staggered arrangement and so that a drain hole defined by the PCB is shared by the riding heat sinks.

In one aspect, a system is provided. The system includes a vertically-oriented printed circuit board (PCB); and a cage assembly having a first cage and a second cage each arranged to receive an optical module and having an integrated heat sink and a riding heat sink that includes a fin array, wherein the first and second cages are arranged so that the fin arrays are nested in a staggered arrangement and so that a drain hole defined by the PCB is common to each of the riding heat sinks and each of the integrated heat sinks.

In one aspect, a system is provided. The system includes a vertically-oriented printed circuit board (PCB); and a cage assembly having a first cage and a second cage arranged in a back-to-back configuration and each arranged to receive an optical module, each of the first and second cages having an integrated heat sink and a riding heat sink that includes a fin array, wherein the first and second cages are arranged so that the fin arrays are nested in a staggered arrangement and so that a drain hole defined by the PCB is common to each of the riding heat sinks and each of the integrated heat sinks.

In one aspect, a system is provided. The system includes a vertically-oriented printed circuit board (PCB); and a cage assembly having a first cage and a second cage arranged in a back-to-back configuration and each arranged to receive an optical module, wherein the first and second cages are arranged so that at least one cage hole formed by the PCB is shared between the first and second cages.

In another aspect, in combination with any example system above or below, wherein the at least one cage hole is a plurality of cage holes that includes a pair of large cage holes flanked by small cage holes, with the large cage holes being staggered with their respective nearest neighbor small cage hole both vertically and laterally.

In another aspect, in combination with any example system above or below, wherein the at least one cage hole is an angled oblong slot.

### Example Embodiments

Some vertical line card (VLC) systems have a printed circuit board (PCB) oriented vertically within a chassis, rather than horizontally. Optical devices and an integrated circuit (IC), such as a switching/routing application-specific circuit (ASIC), can be mounted to the vertically-oriented PCB. During operation, an air flow can be directed through the VLC system from the front of the chassis out the back. The vertically-oriented PCB can cause blockage of rearward air flow without the presence of notches or cutouts in the PCB. Since ventilation notches or cutouts in the vertically-oriented PCB are at the expense of area available for component placement and routing traces, there is typically a design trade-off between high speed electrical routing and thermal design of the VLC system. Striking a balance between these design considerations has presented certain challenges. Various embodiments of vertical line card (VLC) systems are disclosed herein that can address such challenges.

In one example aspect, a VLC system includes a vertically-oriented PCB, an IC mounted to the PCB (e.g., a switching/routing ASIC), and at least one cage assembly having cages arranged to receive optical connectors. Optical signals can travel via a signal path from the optical connectors to optical-to-electrical converters, which can convert the optical signals to electrical signals. The electrical signals can travel along the signal path to the IC for processing by way of respective electrical traces disposed on the PCB. In addition, electrical signals from the IC can travel the opposite way along the signal path via the electrical traces to respective electrical-to-optical converters, which can convert the electrical signals to optical signals. The optical signals can travel along the signal path through the cages and to their respective optical connectors. During operation, the optical connectors, the IC, the signal converter devices, and other components of the VLC system can generate a thermal load.

The VLC system of the present disclosure can include a novel cage arrangement, PCB hole layout, and cage venting features that can facilitate management of the thermal load of the VLC system whilst also efficiently using the PCB area for high speed electrical routing. In one or more examples, the cages can be arranged in a splayed layout so that the cages “angularly fan out” with respect to the IC, e.g., similar to angled seating in a theatre. The PCB can define cage holes arranged complementary to the splayed layout of the cages, with the cage holes being aligned with the cages along a primary airflow direction. In this way, airflow can travel by an optical connector received within a cage, through the cage, and then through the PCB via the cage holes to a rear side of the PCB. The PCB can also define drain holes, which can be offset from the cages along the primary airflow direction. The cages can include cage vents that allow a portion of the air passing through a given cage to escape and flow toward a nearby drain hole, where the portion of air can pass to the rear side of the PCB. The cage vents and arrangement of the drain holes can thus promote lateral and/or vertical flow forward of the PCB, which can provide enhanced cooling of nearby components, such as the optical connectors, cages, signal converters, IC, etc. arranged forward of the PCB. Accordingly, forward of the PCB, there is airflow flowing along the primary airflow direction as well as laterally and/or vertically, for enhanced cooling.

Moreover, the angular fan out of the cages can create lateral flow channels that progressively widen in the lateral flow direction away from the IC, with increasing mean cross-sectional area. These widening lateral flow channels allow for reduced pressure losses and greater air flow, and consequently, enhanced cooling. Such an arrangement can also facilitate outward lateral flow to the drain holes, in examples in which the drain holes are arranged laterally outward of the cages (or further away from the IC than are the cages). In addition, the splayed layout of the cages can allow for easier routing and shorter electrical traces while consuming less PCB area with the PCB hole layout disclosed herein, which may allow for fewer PCB layers and lower fabrication cost, among other possible benefits. For instance, trace route lengths from corner connectors can be made shorter compared to a rectangular layout of equivalent spacing (e.g., with a 18 mm vertical pitch). The angular fan out of the cages can also create vertical flow channels, which can further enhance cooling of components forward of the vertically-oriented PCB. A cage frame supporting the cages can also include exterior venting features as well as structural reinforcing features that facilitate cooling airflow. Example VLC systems are provided below.

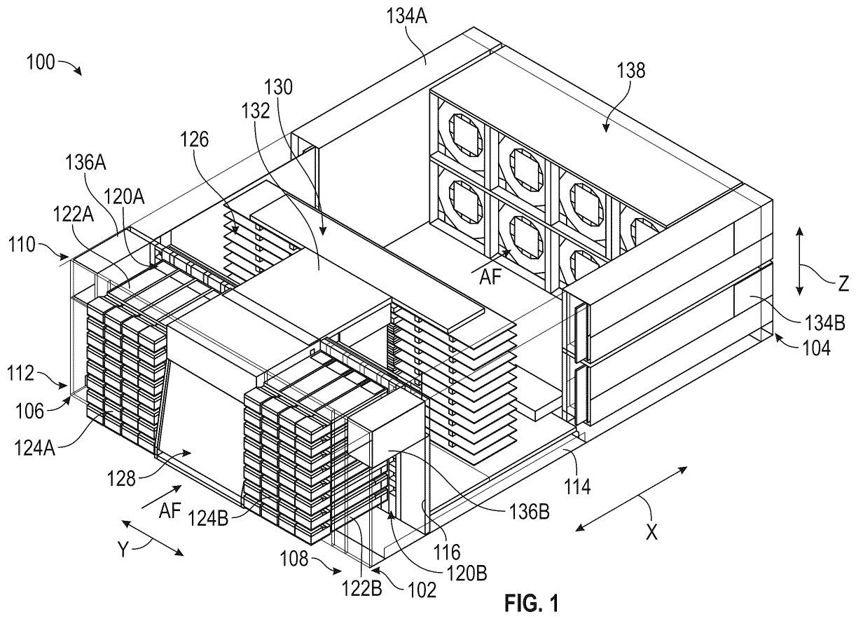

FIG. 1 is a perspective view of a vertical line card (VLC) system, or VLC system 100, according to one or more embodiments of the present disclosure. The VLC system 100 can be configured as a router for networking applications, for example. For reference, the VLC system 100 defines an X-direction, a Y-direction, and a Z-direction, which are mutually perpendicular to one another. The X-direction is a longitudinal direction, the Y-direction is a lateral direction, and the Z-direction is a vertical direction in this example. The VLC system 100 extends between a front 102 and a back 104 along the X-direction, between a first side 106 and a second side 108 along the Y-direction, and between a top 110 and a bottom 112 along the Z-direction.

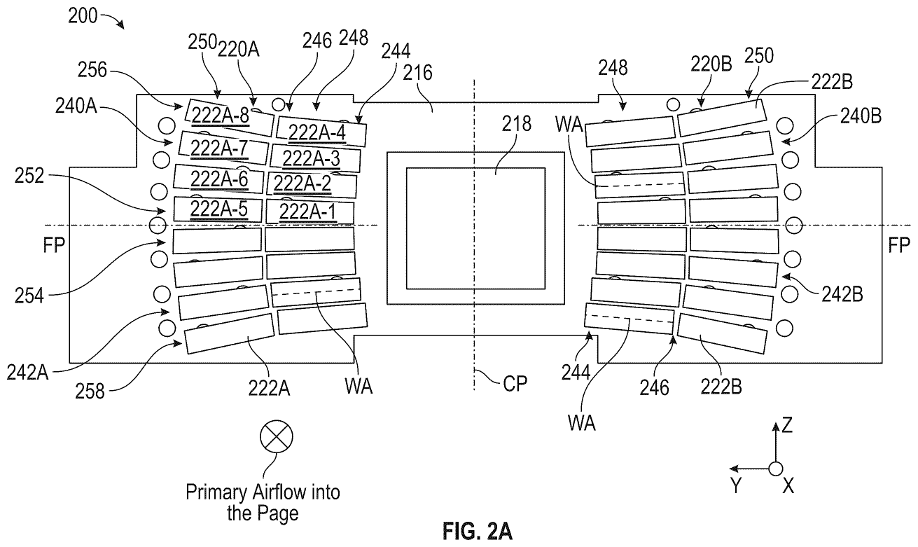

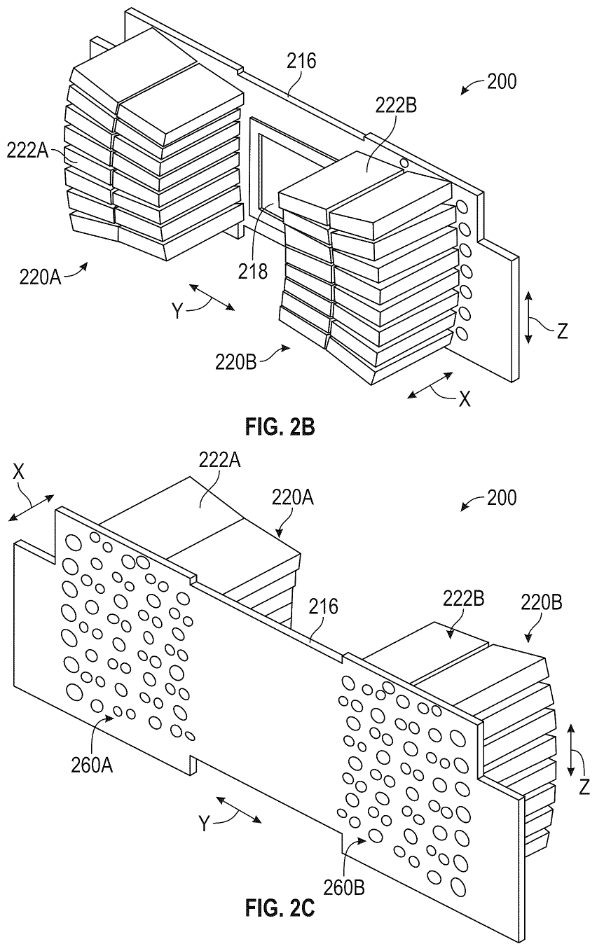

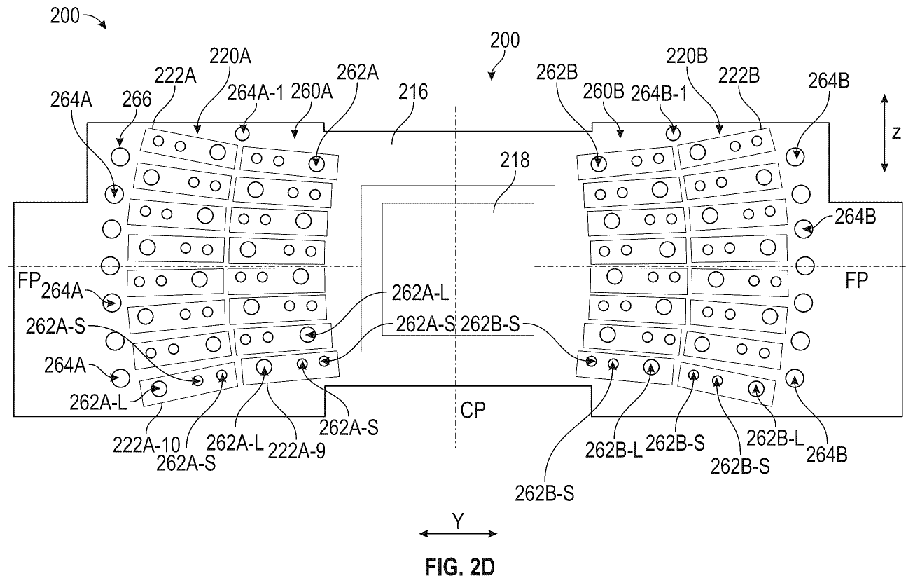

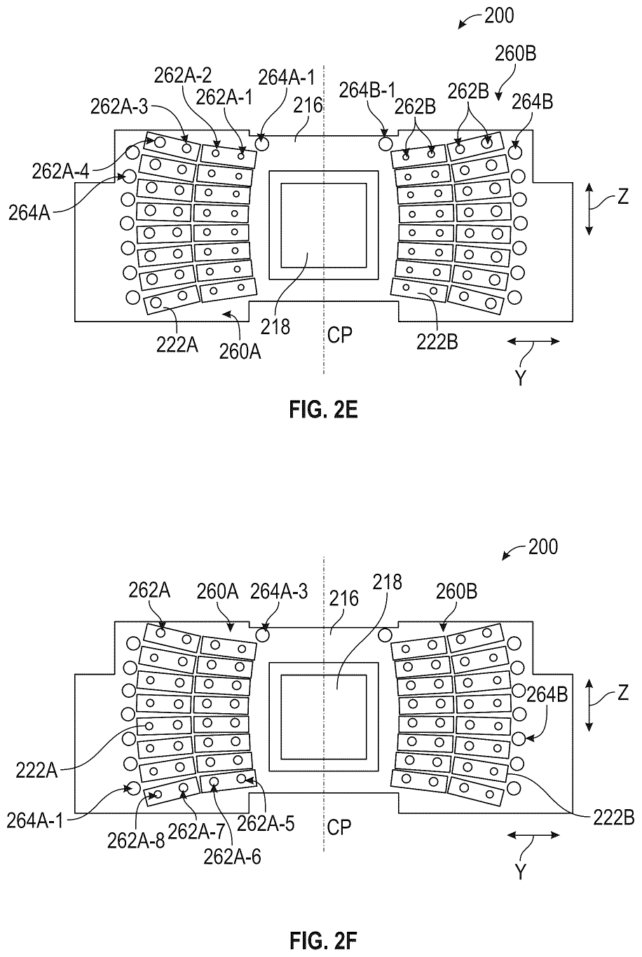

As depicted in FIG. 1, the VLC system 100 includes a chassis 114 that supports and encloses components of the VLC system 100. In FIG. 1, some portions of the chassis 114 are shown transparent for illustrative purposes. The VLC system 100 includes a vertically-oriented printed circuit board (PCB), or PCB 116. The PCB 116 has a thickness along the X-direction and extends vertically between the top 110 and the bottom 112 of the VLC system 100. A vertically-oriented integrated circuit (IC), or IC 118, is mounted to a forward face of the PCB 116, which is hidden in FIG. 1 but shown in FIG. 2. The IC 118 can be an application-specific integrated circuit (ASIC), such as a network processing unit (NPU) or switching/routing IC.

The VLC system 100 also includes at least one cage assembly. In this example, the VLC system 100 includes a first cage assembly 120A and a second cage assembly 120B, which are located generally at the front 102 and are arranged on opposite sides of the IC 118 as depicted in FIG. 2. The first cage assembly 120A has a plurality of first cages 122A, and similarly, the second cage assembly 120B has a plurality of second cages 122B. The first cages 122A, or optical cages, can include ports for receiving first optical connectors 124A, also called optical modules. Optical signals can travel via a signal path from the first optical connectors 124A to respective optical-to-electrical converters, which can convert the optical signals to electrical signals. The electrical signals can travel along the signal path to the IC 118 for processing by way of respective electrical traces disposed on the PCB 116. In addition, electrical signals from the IC 118 can travel the opposite way along the signal path via the electrical traces to respective electrical-to-optical converters, which can convert the electrical signals to optical signals. The optical signals can travel along the signal path through their respective first cages 122A to their respective first optical connectors 124A.

The second cages 122B can include ports for receiving second optical connectors 124B. Optical signals can travel via a signal path from the second optical connectors 124B to respective optical-to-electrical converters, which can convert the optical signals to electrical signals. The electrical signals can travel along the signal path to the IC 118 for processing by way of respective electrical traces disposed on the PCB 116. In addition, electrical signals from the IC 118 can travel the opposite way along the signal path via the electrical traces to respective electrical-to-optical converters, which can convert the electrical signals to optical signals. The optical signals can travel along the signal path through their respective second cages 122B to their respective second optical connectors 124B.

As further depicted in FIG. 1, the VLC system 100 includes an IC heat sink 126 having a front fin stack 128 and a rear fin stack 130. The front fin stack 128 is disposed forward of the PCB 116 along the X-direction and between the first and second cage assemblies 120A, 120B along the Y-direction. The rear fin stack 130 is disposed rearward of the PCB 116 along the X-direction. The front fin stack 128 can include a plurality fins that can facilitate cooling of the IC 118 (FIG. 2). The rear fin stack 130 can facilitate cooling of the IC 118 and other components, such as a power module (e.g., a voltage regulator module (VRM)) disposed rearward of the PCB 116. The VLC system 100 also includes a vapor chamber 132, which is arranged to transfer heat away from the IC 118 (FIG. 2) and to spread the heat to the IC heat sink 126.

The VLC system 100 also includes power supply units, or PSUs 134A, 134B, located at the first and second sides 106, 108 at or near the back 104. The PSUs 134A, 134B can supply electrical power to the power-consuming devices of the VLC system 100. First and second cooling ducts 136A, 136B can be arranged to supply cooling air to the PSUs 134A, 134B. The first and second cooling ducts 136A, 136B each include inlets at the front 102.

A plurality of fans 138 are stacked at the back 104 and are arranged to move a fluid (e.g., air) through the VLC system 100, with a primary airflow direction extending parallel with the X-direction. Generally, airflow AF can be moved through the VLC system 100 from the front 102 to the back 104. A first portion of the airflow AF can flow through the first cages 122A of the first cage assembly 120A, through holes of the PCB 116, and rearward along the X-direction toward the fans 138. A second portion of the airflow AF can flow through the second cages 122B of the second cage assembly 120B, through holes of the PCB 116, and rearward along the X-direction toward the fans 138. A third portion of the airflow AF can flow through the front fin stack 128 of the IC heat sink 126 and can ultimately make its way toward the fans 138. Fourth and fifth portions of the airflow AF can enter the respective inlets of the cooling ducts 136A, 136B and can flow toward their respective PSUs 134A, 134B for providing cooling thereto.

As will be explained further below, the first and second cages 122A, 122B of the first and second cage assemblies 120A, 120B can be disposed in an arrangement and can include venting features that can enhance cooling of the IC 118 and other components of the VLC system 100. Further, holes defined by the PCB 116 can be arranged so as to enhance cooling and can also provide more available space for electrical traces.

With reference now to FIGS. 2A through 2D, various views of an assembly 200 for a VLC system are depicted. The assembly 200 can be implemented in the VLC system 100 of FIG. 1, for example. The assembly 200 includes a vertically-oriented PCB, or PCB 216, a vertically-oriented IC, or IC 218, and first and second cage assemblies 220A, 220B having first and second cages 222A, 222B. The IC 218 is mounted to a forward face of the PCB 216. The IC 218 can be an ASIC, such as an NPU or switching/routing IC. The first cage assembly 220A and the second cage assembly 220B are disposed on opposite sides of the IC 218. The first and second cage assemblies 220A, 220B can be symmetrically arranged with respect to a central plane CP. The first and second cages 222A, 222B can include ports for receiving optical connectors. For reference, the assembly 200 can define an X-direction, a Y-direction, and a Z-direction, which are mutually perpendicular to one another. The X-direction is a longitudinal direction, the Y-direction is a lateral direction, and the Z-direction is a vertical direction in this example. The directions of FIGS. 2A through 2D can correspond to the directions of FIG. 1.

In the illustrated embodiment of FIGS. 2A, 2B, 2C, and 2D, the first cages 222A are arranged in a splayed layout. That is, the first cages 222A angularly fan out with respect to the IC 118 (similar to angled seating in a theatre). The first cages 222A are arranged in the splayed layout so that each cage is angled or tilted with respect to the Y-direction, or rather, a direction that is perpendicular to the Z-direction (e.g., a vertical direction) and the X-direction (e.g., a longitudinal direction). Stated yet another way, a width axis WA of each cage of the first cages 222A is angled with respect to the Y-direction. Similarly, mirroring the first cages 222A, the second cages 222B are arranged in a splayed layout, or rather, the second cages 222B angularly fan out with respect to the IC 118. The second cages 222B are arranged in the splayed layout so that each cage is angled or tilted with respect to the Y-direction, or rather, a direction that is perpendicular to the Z-direction (e.g., a vertical direction) and the X-direction (e.g., a longitudinal direction). Stated yet another way, a width axis WA of each cage of the second cages 222B is angled with respect to the Y-direction.

For the first cage assembly 220A, the first cages 222A are arranged in the splayed layout so that a first or upper set 240A of the first cages 222A are arranged above a fan out plane FP and a second or lower set 242A of the first cages 222A are arranged below the fan out plane FP. The fan out plane FP extends perpendicular to the Z-direction (e.g., a vertical direction). The first cages 222A of the upper set 240A are angled with a negative angle with respect to the fan out plane FP and the first cages 222A of the lower set 242A are angled with a positive angle with respect to the fan out plane FP. For the second cage assembly 220B, the second cages 222B are arranged in the splayed layout so that a first or upper set 240B of the second cages 222B are arranged above the fan out plane FP and a second or lower set 242B of the second cages 222B are arranged below the fan out plane FP. Further, for the second cage assembly 220B, the second cages 222B of the upper set 240B are angled with a positive angle with respect to the fan out plane FP and the second cages 222B of the lower set 242B are angled with a negative angle with respect to the fan out plane FP.

Further, each cage of the first and second cages 222A, 222B has an inner end 244 and an outer end 246, with the inner end 244 of a given cage of the first and second cages 222A, 222B being disposed closer to the central plane CP than the outer end 246 of the given cage. In addition, in some examples, the first and second cages 222A, 222B are arranged in the splayed layout so that, for a given cage of the first and second cages 222A, 222B, the inner end 244 of the given cage is arranged closer to the fan out plane FP than the outer end 246 of the given cage. In this regard, the inner ends of the cages are angled toward the fan out plane FP. Accordingly, the cages angularly fan out, as noted above.

In some embodiments, the first cages 222A are arranged in the splayed layout in at least two columns, including a first column 248 and a second column 250, with the second column 250 being arranged outward of the first column 248 with respect to the IC 118 (or central plane CP), e.g., along the Y-direction. For the first column 248, the angle of the first cages 222A with respect to the fan out plane FP can increase in increments from one row to the next, as the rows extend away from the fan out plane FP. Stated another way, for the of the upper set 240A, the angle of the first cages 222A with respect to the fan out plane FP can increase in increments from the center row 252 to a top row 256, and, for the lower set 242A, the angle of the first cages 222A with respect to the fan out plane FP can increase in increments from the center row 254 to a bottom row 258. For instance, the angle can start at 1 degree for the center row(s) 252, 254 of the first column 248, and then increase in increments of 2 degrees, as the rows extend away from the fan out plane FP.

As shown in FIG. 2, for example, the cage 222A-1 positioned in the center row 252 of the first column 248 can be angled at 1 degree with respect to the fan out plane FP. The cage 222A-2 positioned in the first column 248 in the row adjacent to and above the center row 252 can be angled at 2 degrees with respect to the fan out plane FP. The cage 222A-3 positioned in the first column 248 in the row adjacent to and below a top row 256 can be angled at 4 degrees with respect to the fan out plane FP. The cage 222A-4 positioned in the first column 248 in the top row 256 can be angled at 6 degrees with respect to the fan out plane FP. These increments can be mirrored for the first column 248 of the lower set 242A of the first cages 222A.

For the second column 250, the angle of the first cages 222A with respect to the fan out plane FP can increase in increments from one row to the next, as the rows extend away from the fan out plane FP. Stated differently, for the of the upper set 240A, the angle of the first cages 222A with respect to the fan out plane FP can increase in increments from the center row 252 to the top row 256, and, for the lower set 242A, the angle of the first cages 222A with respect to the fan out plane FP can increase in increments from the center row 254 to the bottom row 258. For instance, the angle can start at 2 degrees for the center row(s) 252, 254 of the first column 248, and then increase in increments of 4 degrees, as the rows extend away from the fan out plane FP. Accordingly, the increments for the second column 250, or outer column, can be greater than the increments for the first column 248, or inner column.

As shown in FIG. 2, for example, the cage 222A-5 positioned in the center row 252 of the second column 250 can be angled at 2 degrees with respect to the fan out plane FP. The cage 222A-6 positioned in the second column 250 in the row adjacent to and above the center row 252 can be angled at 4 degrees with respect to the fan out plane FP. The cage 222A-7 positioned in the second column 250 in the row adjacent to and below the top row 256 can be angled at 8 degrees with respect to the fan out plane FP. The cage 222A-8 positioned in the second column 250 in the top row 256 can be angled at 12 degrees with respect to the fan out plane FP. These increments can be mirrored for the second column 250 in the lower set 242A of the first cages 222A.

The increments noted above for the first cages 222A can be mirrored for the second cages 222B of the second cage assembly 220B.

In other examples, the first cages 222A and/or the second cages 222B can other suitable increments therebetween. Further, while the first and second cage assemblies 220A, 220B are arranged respectively as 2×8 configurations (i.e., 2 columns by 8 rows), the first and second cage assemblies 220A, 220B can have other configurations in other example embodiments.

As further shown in FIGS. 2C and 2D, the PCB 216 can define a plurality of holes, which can be circular rather than oblong slots that have been traditionally used. FIG. 2C shows a rear view of the assembly 200 while FIG. 2D shows a front view of the assembly 200 with the first and second cages 222A, 222B transparent so that the holes defined by the PCB 216 are visible for illustration purposes. Generally, the holes defined by the PCB 216 allow airflow traveling through the first and second cages 222A, 222B to pass through the PCB 216 (and onward toward fans arranged at the back of a VLC system).

The PCB 216 can define a first set 260A of holes and a second set 260B of holes. The holes of the first set 260A are associated with the first cage assembly 220A and the holes of the second set 260B are associated with the second cage assembly 220B. The holes of the first and second sets 260A, 260B can be defined on opposing sides of the IC 218, e.g., along the Y-direction. The PCB 216 can define the holes so that the first and second sets 260A, 260B each include drain holes and cage holes. The cage holes can be of varying size and can be arranged complementary to the splayed layout of the first and second cages 222A, 222B. The cage holes can vary in size in that the cage holes can include relatively large cage holes and relatively small cage holes. The drain holes can be larger than the large cage holes (in diameter).

As shown in FIGS. 2C and 2D, the first set 260A of holes includes cage holes 262A and drain holes 264A. Each cage hole 262A can be aligned, at least in part, with one of the first cages 222A along the Z-direction and the Y-direction (e.g., vertical and lateral directions), while the drain holes 264A are not. Stated another way, the PCB 216 can define the cage holes 262A so that they are aligned with their respective first cages 222A along a primary airflow direction (the X-direction in this example), while the drain holes 264A are offset from the first cages 222A along the primary airflow direction. Similarly, the second set 260B of holes includes cage holes 262B and drain holes 264B. Each cage hole 262B can be aligned, at least in part, with one of the second cages 222B along the Z-direction and the Y-direction (e.g., vertical and lateral directions), while the drain holes 264B are not. Stated differently, the PCB 216 can define the cage holes 262B so that they are aligned with their respective second cages 222B along the primary airflow direction (the X-direction in this example), while the drain holes 264B are offset from the second cages 222B along the primary airflow direction.

In one or more examples, each row of cages (or each row of cage holes) has an associated drain hole. For instance, as depicted in FIGS. 2C and 2D, the first set 260A of holes includes eight (8) drain holes 264A, with each of the drain holes 264A being associated with one of the eight (8) rows of the first cages 222A (or each of the eight (8) rows of the cages holes 262A). Similarly, the second set 260B of holes includes eight (8) drain holes 264B, with each of the drain holes 264B being associated with one of the eight (8) rows of the second cages 222B (or each of the eight (8) rows of the cages holes 262B).

In one or more examples, for at least one row of cages, the drain hole associated with that row is defined outward of that row (or outermost cage of that row) with respect to the central plane CP. For instance, as shown in FIG. 2D, some of the drain holes 264A are disposed in an outer column 266, and the drain holes 264A in the outer column 266 are arranged outward of the first cages 222A with respect to the central plane CP (or the IC 218) along the Y-direction. That is, the drain holes 264A are defined outward of the outermost cage of their respective rows with respect to the central plane CP (or the IC 218). In FIG. 2D, the drain holes 264A associated with the second through eighth rows of the cages (the rows below topmost row) are arranged in the outer column 266. The drain holes 264A of the outer column 266 can be defined by the PCB 216, at least in part, vertically above the outermost cage of their respective rows (or outermost cage hole of their respective rows), which can facilitate directing the relatively warm air that has passed through the first cages 222A through the drain holes 264A. In at least one example, such as in the embodiment of FIG. 2D, a top drain hole 264A-1 of the drain holes 264A is offset from the topmost row of the first cages 222A (or the topmost rows of cage holes) along the Z-direction. Such an arrangement can allow for efficient use of space of the PCB 216 and facilitate the splayed layout of the first cages 222A.

The second drain holes 264B of the second set 260B of holes can mirror the arrangement of the first drain holes 264A of the first set 260A of holes, e.g., as shown in FIG. 2D.

In one or more examples, the PCB 216 can define cage holes so that each cage is aligned with a large cage hole and a pair of small cage holes, e.g., along the Z-direction and Y-direction. For instance, as shown in FIGS. 2C and 2D for the bottommost row of the first set 260A of holes, the cage holes are arranged so that an inner first cage 222A-9 of the bottommost row is aligned with a large cage hole 262A-L and a pair of small cage holes 262A-S and so that an outer first cage 222A-10 of the bottommost row is aligned with a large cage hole 262A-L and a pair of small cage holes 262A-S. In FIG. 2D, each cage is aligned with a large cage hole 262A-L and a pair of small cage holes 262A-S, including the cage holes of the second set 260B.

Further, in one or more examples, the PCB 216 can define the cage holes so that, for a given row of cage holes, the cage holes alternate between pairs of small cage holes and large cage holes. For a given row, the alternating pattern can continue from one column to the next, e.g., from the inner column to the outer column, or vice versa. For instance, as shown in FIGS. 2C and 2D, for the bottommost row of the first set 260A of holes, the cage holes are defined by the PCB 216 so that the cage holes alternate between pairs of small cage holes 262A-S and large cage holes 262A-L. The inner first cage 222A-9 is aligned with a pair of small cage holes 262A-S arranged inward of a large cage hole 262A-L. The outer first cage 222A-10 is aligned with a pair of small cage holes 262A-S arranged inward of a large cage hole 262A-L. Thus, the alternating pattern of a pair of small cage holes to large cage hole continues from the first column of cage holes associated with the inner first cage 222A-9 to the second column of the cage holes associated with the outer first cage 222A-10.

In addition, in one or more examples, the PCB 216 can define the cage holes so that the alternating pattern is staggered from one row to the next. For instance, the alternating pattern associated with a first row can start with a large cage hole while the alternating pattern associated with a second row adjacent to the first row can start with a pair of small cage holes. This hole arrangement allows for wider PCB routing pathways at the most congested regions near the central IC and allows more possibilities for routing escape traces from the connectors. For instance, as shown in FIGS. 2C and 2D, the alternating pattern starts at the inner end of the bottommost row with a pair of small holes 262A-S, and the next row adjacent to the bottommost row starts with the alternating pattern at the inner end with a large cage hole 262A-L. The other rows are likewise staggered for the first set 260A. The rows of cage holes are likewise alternating and staggered for the second set 260B of holes.

In one or more other examples, the PCB 216 can define cage holes so that, for a given row of cage holes, the cage holes decrease in size the closer the cage holes are to the IC 218. Stated differently, the cage holes increase in size the further away the cage holes are from the IC 218, with the cage holes sequentially increasing in size. For instance, as shown in FIG. 2E, each of the eight (8) rows of cage holes of the first set 260A have four (4) cage holes each. The topmost row of cage holes of the first set 260A is representative. The topmost row of cage holes includes a first cage hole 262A-1, a second cage hole 262A-2, a third cage hole 262A-3, and a fourth cage hole 262A-4. The first cage hole 262A-1 is the innermost cage hole, the second cage hole 262A-2 is the second innermost cage hole, the third cage hole 262A-3 is the third innermost cage hole, and the fourth cage hole 262A-4 is the outermost cage hole of the topmost row of cage holes, with respect to the central plane CP (or IC 218). As shown, the cage holes 262A-1, 262A-2, 262A-3, 262A-4 decrease in size the closer the cage holes are to the IC 218. Each row of cage holes of the first set 260A can be similarly configured, as can the rows of cage hole of the second set 260B.

In one or more further examples, for at least one row of the cages, the drain hole associated with that row is defined, at least in part, inward of the row (or innermost cage of the row) with respect to the central plane CP (or IC 218). For instance, as shown in FIG. 2E, the topmost row of cage holes has a drain hole 264A-1 associated therewith, and as illustrated, the drain hole 264-1 is defined, at least in part, inward of the row (or innermost cage of the row) with respect to the central plane CP (or IC 218). This can advantageously allow for the cages to angularly fan out closer to the top side of the PCB 216, for example.

In one or more other examples, the PCB 216 can define cage holes so that, for a given row of cage holes, the cage holes decrease in size the closer the cage holes are to a drain hole associated with the given row of cage holes. In such examples, the sequence of the top row can be reversed compared to the other rows due to the placement of the drain hole associated with the top row.

For instance, as shown in FIG. 2F, the bottommost row of cage holes of the first set 260A is representative. As depicted, the bottommost row of cage holes includes a first cage hole 262A-5, a second cage hole 262A-6, a third cage hole 262A-7, and a fourth cage hole 262A-8. The first cage hole 262A-5 is the innermost cage hole, the second cage hole 262A-6 is the second innermost cage hole, the third cage hole 262A-7 is the third innermost cage hole, and the fourth cage hole 262A-8 is the outermost cage hole of the bottommost row of cage holes, with respect to the central plane CP (or IC 218). As illustrated, the cage holes 262A-5, 262A-6, 262A-7, 262A-8 decrease in size the closer the cage holes are to a drain hole 264A-2 associated with the bottommost row of cage holes. The sequence of the topmost row of the first set 260A can be reversed compared to the other rows of the first set 260A due to the placement of the drain hole 264A-3 associated with the topmost row being arranged inward, at least in part, of the cage holes 262A of the topmost row with respect to the central plane CP (or IC 218). Each row of cage holes of the first set 260A can be similarly configured, as can the rows of cage hole of the second set 260B. The cage holes sized according to the depicted example embodiment of FIG. 2F can facilitate lateral movement of the airflow toward the drain holes.

In one or more examples, the cages can include cage vents at their respective rear portions to allow airflow to escape the cages (upstream of the cage holes and drain holes defined by the PCB). The cage vent of a given cage can be defined around a periphery of the rear portion of the given cage. For instance, in some embodiments, a bottom wall, sidewalls, and a top wall of a cage can form the cage vent by defining a plurality of perforations. The cage vent can define the perforations by vent panels or by the walls of the cage itself.

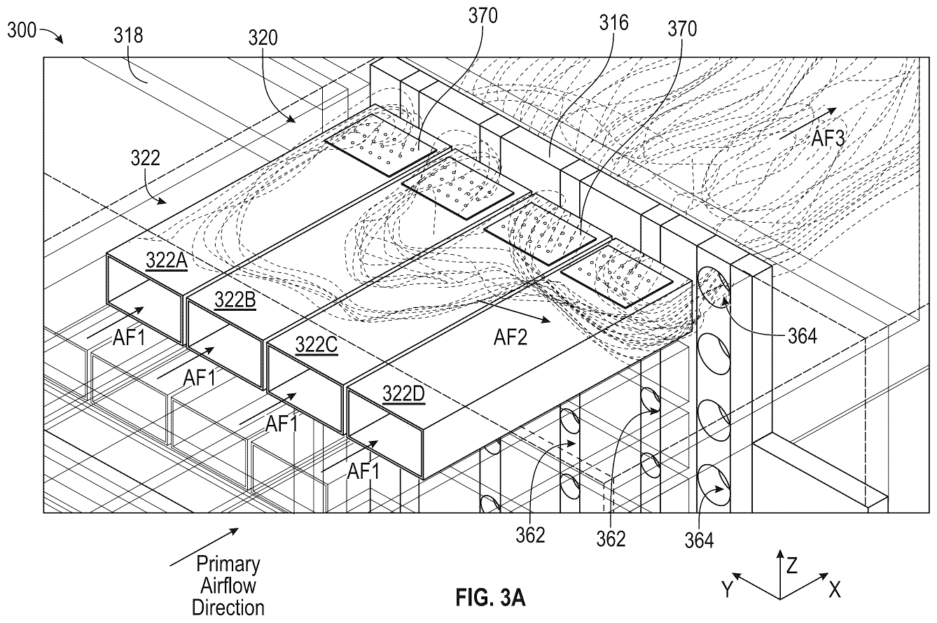

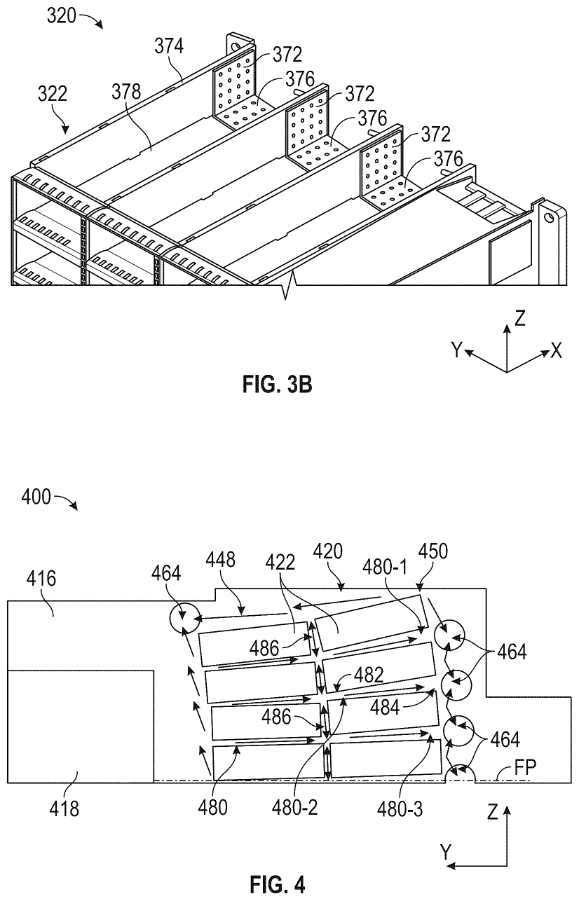

By way of example, FIG. 3A is a close-up, perspective view of an assembly 300 for a VLC system. The assembly 300 can be implemented in the VLC system 100 of FIG. 1, for example. The assembly 300 has a cage assembly 320 having cages 322 arranged relative to a vertically-oriented PCB 316. An IC 318 is mounted to the PCB 316. The PCB 316 defines a plurality of cage holes 362 and a plurality of drain holes 364. The cage holes 362 are aligned with cages 322 of the cage assembly 320 along a primary airflow direction, which is the X-direction in this example. The drain holes 364 are offset from the cages 322 along the primary airflow direction, or rather, are not aligned with the cages 322 along the primary airflow direction. The cage assembly 320 includes, among other rows, a top row of cages having a first cage 322A, a second cage 322B, a third cage 322C, and a fourth cage 322D. The first cage 322A is the innermost cage of the top row while the fourth cage 322D is the outermost cage, with respect to the IC 318 along the Y-direction. The cages 322A-322D each include a cage vent 370 at their respective rear portions (the cages of the other rows can likewise have cage vents). In FIG. 3A, the cage vents 370 are arranged as panels each defining a plurality of perforations that allow air to escape the cages 322A-322D and flow laterally to the drain holes 364.

During operation, an airflow can be moved through the VLC system (e.g., by fans as shown in FIG. 1). A first portion of the airflow AF1 flowing along the primary airflow direction (or X-direction in this example) can flow into the cages 322 (and around optical connectors received in the cages 322; the optical connectors are not shown in FIG. 3A). Some of the first portion of the airflow AF1 can flow through the cage holes 362 defined by the PCB 316. Some of the first portion of the airflow AF1 flowing through the cages 322 can escape through the perforations in the cage vents 370, e.g., as shown in FIG. 3A. Notably, the escaped air can flow laterally (or a direction generally perpendicular to the primary airflow direction), as represented by the airflow AF2. The airflow AF2 can flow generally laterally toward the drain hole 364 associated with a give row of holes. In some instances, some of the airflow AF2 can even flow slightly forward away from the PCB 316 along the X-direction, or rather, opposite the primary airflow direction. This generally lateral flow forward of the PCB 316 can enhance the cooling of the IC 318, the cages 322 and components thereof, the optical connectors, and other components arranged forward of the PCB 316 along the X-direction. The lateral flow, or airflow AF2, can flow toward and through the drain holes 364 to pass to the rear side of the PCB 316. Airflow AF3 represents the airflow rearward of the PCB 316.

While the cages 322 in FIG. 3A include cage vents 370 at their respective top walls, in other examples, the cages 322 can, additionally or alternatively to the cage vents 370 (or top wall vents), include cage vents at their respective sidewalls. For instance, FIG. 3B shows the cages 322 each having a sidewall cage vent 372 at their respective sidewalls 374. The sidewall cage vents 372 are each arranged as panels having a plurality of perforations. The sidewall cage vents 372 can allow air to flow laterally from one cage to another, or rather, from cage-to-cage along the Y-direction, which can facilitate airflow to the drain holes.

In one or more other examples, the cages 322 can, additionally or alternatively to the other cage vents, include cage vents at their respective bottom walls. The cage vents at the bottom walls can be arranged face-to-face with a top wall cage vent of an adjacent row, or can be spaced therefrom, particularly for cages having splayed layouts. In FIG. 3B, the cages 322 have bottom wall cage vents 376 at their respective bottom walls 378. The bottom wall cage vents 376 can allow air to flow vertically from a cage of one row to a cage of another row. This can allow incoming airflow to be more evenly distributed to the cage rows of the cage assembly 320, among other benefits.

The cages 122A, 122B, 222A, 222B of the disclosed embodiments can include the cage venting features described above and illustrated in FIGS. 3A and 3B.

In one or more further examples, cages of a cage assembly can be arranged in a splayed layout so that flow channels are defined between the cages. The flow channels can be defined as laterally-extending flow channels. Due to the splayed layout of the cages, the laterally-extending flow channels can progressively increase in cross-sectional area as the laterally-extending flow channels extend away from an IC mounted to a vertically-oriented PCB. As example is provided below.

FIG. 4 depicts a close-up view of a portion of an assembly 400 for a VLC system. The assembly 400 can be implemented in the VLC system 100 of FIG. 1, for example. The assembly 400 has a cage assembly 420 having a plurality of cages 422, which can each having venting features, such as any combination of the venting features illustrated in FIGS. 3A and 3B and described in the accompanying text. The cage assembly 420 is arranged relative to a forward side of a vertically-oriented PCB 416. An IC 418 is mounted to the PCB 416. As depicted in FIG. 4, the cages 422 arranged in a splayed layout so that the cages 422 angularly fan out with respect to the IC 418. The angular fan out of the cages 422 creates laterally-extending flow channels 480 between the cages 422. For the outer column of cages, for example, a first flow channel 480-1 is formed between the topmost cage and the second topmost cage. A second flow channel 480-2 is formed between the second topmost cage and a third topmost cage. A third flow channel 480-3 is formed between the third topmost cage and a fourth topmost cage (the cage immediately above the fan out plane FP in FIG. 4). Laterally-extending flow channels can be formed between other cages of the cage assembly 420 as well.

As noted, the flow channels 480 can progressively increase in cross-sectional area as the flow channels 480 extend away from the IC 418, e.g., along the Y-direction. The second flow channel 480-2 is representative. As depicted in FIG. 4, an inner end 482 of the second flow channel 480-2 has a smaller cross-sectional area than does an outer end 484 of the second flow channel 480-2. The cross-sectional area of the second flow channel 480-2 progressively increases from the inner end 482 to the outer end 484. The increasing cross-sectional area of the flow channels 480 can result in reduced pressure losses and greater air flow, and consequently, enhanced cooling. Air can escape the cages 422 through their top wall, sidewall, and/or bottom wall cage vents and can flow along the laterally-extending flow channels 480 to drain holes 464 defined by the PCB 416, and the angular fan out of the cages 422 can facilitate lateral airflow to the drain holes 464. The lateral airflow can enhance the cooling of the components forward of the PCB 416.

In addition to the laterally-extending flow channels 480, which generally extend laterally along the Y-direction, the cages 422 can also form vertical flow channels 486 therebetween due to their splayed layout. For instance, vertical flow channels 486 can be formed between cages of adjacently arranged cage columns. For instance, for the topmost row of cages, one vertical flow channel 486 can be defined between the cage of a first column 448 (an inner column) and the cage of the second column 450 (an outer column). Vertical flow channels 486 can be formed between the cages of the adjacently arranged first and second columns 448, 450. The vertical flow channels 486 can further reduce pressure losses and provide greater air flow, and consequently, enhanced cooling can be achieved.

The VLC system disclosed herein can provide certain advantages, benefits, and/or technical effects. For instance, the splayed layout of cages and the complementary arrangement of holes defined by the PCB can facilitate easier routing and shorter electrical traces while consuming less PCB area, which may allow for fewer PCB layers and lower fabrication cost, as well as improved VLC system performance. For instance, trace route lengths from corner connectors can be made shorter compared to a rectangular layout of equivalent spacing (18 mm vertical pitch). In addition, the cage venting features of the splayed cages and complementary arrangement of holes defined by the PCB can allow for lateral flow forward of the PCB, which can enhance the cooling of components forward of the vertically-oriented PCB. Vertical flow between the cages can also be achieved with the cage venting features and splayed layout. Moreover, the cages can be arranged in the splayed layout so that lateral flow channels defined between the rows of the cages progressively increase in cross-sectional area as the flow channels extend away from the IC, resulting in reduced pressure losses and greater air flow. The resulting layout can maximize airflow from the inner cages outward to the larger drain holes formed by the PCB.

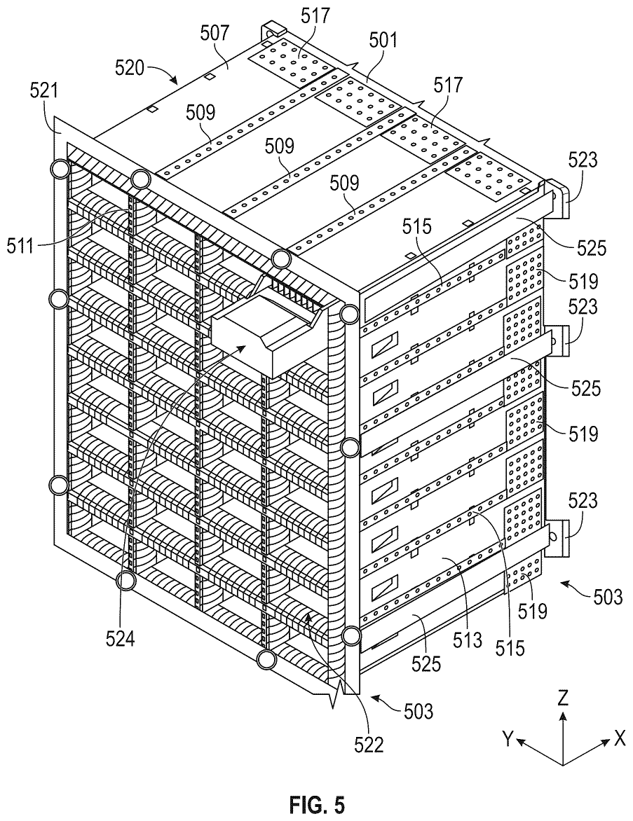

In one or more further examples, a VLC system can include a cage assembly with exterior venting features. For instance, FIG. 5 is a perspective view of a cage assembly 520 that can be incorporated into a VLC system, such as the VLC system 100 of FIG. 1. The cage assembly 520 of FIG. 5 has cages 522 arranged in a 4×8 layout (e.g., four columns by eight rows), however, other cage configurations are possible. The cages 522 are each arranged to receive an optical connector 524 (only one shown in FIG. 5). The cage assembly 520 has a front 503 and a back 505 spaced from one another, e.g., along the X-direction.

The cage assembly 520 has a cage frame 501 supporting the cages 522. The cage frame 501 can include various exterior venting features. In one or more examples, the cage frame 501 can define one or more slots each having a long axis extending along the X-direction and aligned with a wall of at least one of the cages 522. For instance, as depicted in FIG. 5, the cage frame 501 has a top frame wall 507, which forms a top exterior wall of the cage assembly 520. The top frame wall 507 can define at least one slot, and in the depicted embodiment of FIG. 5, the top frame wall 507 defines slots 509 that respective align with walls 511 of the cages 522. The slots 509 are spaced from one another along the Y-direction and each have their long axes extending along the X-direction (the primary airflow direction in this example). In some examples, the slots 509 can extend substantially the length of the cages 522 along the X-direction (e.g., at least seventy-five percent (75%) of the length of the cages 522 along the X-direction). The slots 509 can be aligned with respective walls 511 of the cages 522, or rather, between separating bulkheads to allow for air flow from inner cages of the cages 522 to escape.

In addition or alternatively to the slots 509, the cage frame 501 can include a side frame wall 513 forming an exterior side wall of the cage assembly 520. The side frame wall 513 can define at least one slot. In the illustrated embodiment of FIG. 5, the side frame wall 513 defines a plurality of slots 515. The slots 515 are spaced from one another along the Z-direction and each have their long axes extending along the X-direction (the primary airflow direction in this example). In some examples, the slots 515 can extend substantially the length of the cages 522 along the X-direction (e.g., at least seventy-five percent (75%) of the length of the cages 522 along the X-direction).

The slots 509, 515 can each define a plurality of perforations that allow air to escape vertically and/or laterally out of the cages 522, and this escaped air can flow laterally and/or vertically forward of a vertically-oriented PCB to which the cage assembly 520 is coupled. Lateral and/or vertical airflow forward of the vertically-oriented PCB can facilitate cooling of the IC mounted on the PCB as well as to the optical connectors 524, the cages 522, as well as other components forward of the PCB.

In one or more further examples, the cage frame 501 can include or define at least one frame vent arranged at the back 503 and aligned with at least one of the plurality of cages 522. In FIG. 5, the top frame wall 507 includes or defines a plurality of frame vents 517. The frame vents 517 can each define a plurality of perforations that allow air to escape vertically out of the cages 522. Further, in the illustrated embodiment of FIG. 5, the side frame wall 513 defines a plurality of frame vents 519. The frame vents 519 can each define a plurality of perforations that allow air to escape laterally out of the cages 522. In one or more examples, at least one frame vent 517, 519 includes a plurality of perforations forming at least a 50% open ratio. That is, at least 50% of the area of the frame vents 517, 519 is formed of perforations.

In one or more further examples, the cage assembly 520 can include various structural features that facilitate mounting of the cage assembly 520 in a VLC system relative to a vertically-oriented PCB. In the depicted embodiment of FIG. 5, the cage assembly 520 has a forward stiffener flange 521 arranged to couple with a forward faceplate of a chassis of a VLC system. The forward stiffener flange 521 can extend around the cage frame 501 at the front 503. The forward stiffener flange 521 can act as a reinforcing window frame of the cage assembly 520 at the faceplate of the chassis. The forward stiffener flange 521 can extend in a plane perpendicular to the X-direction.

Further, in one or more examples, the cage assembly 520 has a plurality of tabs 523 arranged at the back 503. The tabs 523 can be vertically spaced from one another, e.g., along the Z-direction. The tabs 523 can be arranged to couple with a vertically-oriented PCB. The tabs 523 can provide additional available space for PCB holes, such as drain holes.

In addition, in one or more examples, the cage assembly 520 can include standoff bars 525 extending between and coupling the forward stiffener flange 521 and the tabs 523. The standoff bars 525 can structurally reinforce the cage assembly 520. The standoff bars 525 can have either round or hex cross sections, for example, and can span along the sides of the cages 522 from the forward stiffener flange 521 to the tabs 523 at the rear. The ends of the standoff bars 525 can be drilled and tapped holes, and screws can fasten from the rear face of a PCB at the back 503 and from the front face of a front panel at the front 503. Additional screws or other mechanical fasteners can attach the upper/lower flanges of the forward stiffener flange 521 to a front panel.

The features illustrated in FIG. 5 and described in the accompanying text can be combined with any of the features described herein, such as the splayed layout of cages, corresponding PCB hole layouts, cage venting features, etc.

In one or more examples, a VLC system can include a cage assembly with at least two cages having external riding heat sinks. The external riding heat sinks of the at least two cages can each have a fin array, and the fins of these fin arrays can be staggered relative to one another. The at least two cages can be arranged so that their riding heat sinks nest with interleaving fins and so that one or more drain holes defined by a PCB arranged at a back of the cages are shared by the riding heat sinks of the at least two cages. The cages of the cage assembly can be arranged to receive optical modules configured as octal small form factor pluggable-riding heat sinks (OSFP-RHS), for example. An example is provided below.

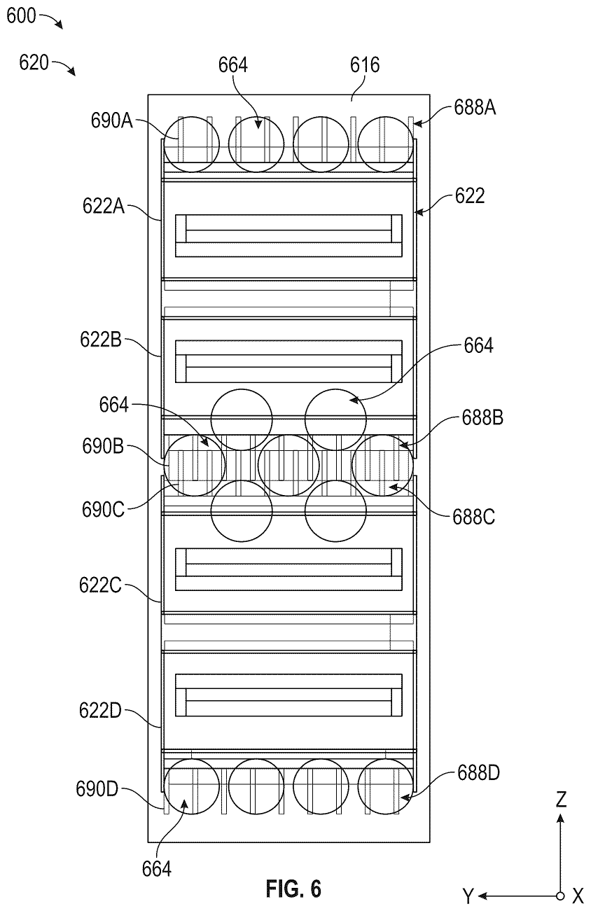

FIG. 6 depicts a front view of an assembly 600 for a VLC system, according to one or more embodiments of the present disclosure. The assembly 600 includes a PCB 616 and a cage assembly 620. The PCB 616 is arranged at the back or back side of the cage assembly 620. The cage assembly 620 includes a plurality of cages 622, including a first cage 622A, a second cage 622B, a third cage 622C, and a fourth cage 622D (collectively the cages 622). The cages 622 are vertically stacked in this example, e.g., along the Z-direction. The first and second cages 622A, 622B are arranged belly-to-belly and the third and fourth cages 622C, 622D are arranged belly-to-belly. The cages 622 can each receive an optical module, such as an OSFP-RHS optical module.

Each one of the cages 622 includes a riding heat sink. As depicted in FIG. 6, the first cage 622A includes a first riding heat sink 688A having first fins 690A arranged in a first configuration. The first cage 622A is oriented right-side up, and thus, the first fins 690A extend vertically upward relative to the walls of the first cage 622A. The second cage 622B, which is arranged belly-to-belly with the first cage 622A, includes a second riding heat sink 688B having second fins 690B arranged in a second configuration. The second cage 622B is oriented upside down, and thus, the second fins 690B extend vertically downward relative to the walls of the second cage 622B. The second fins 690B, which are arranged in the second configuration, are laterally offset from the first fins 690A, which are arranged in the first configuration.

The third cage 622C includes a third riding heat sink 688C having third fins 690C arranged in the first configuration, much like the first fins 690A of the first cage 622A. The third cage 622C is oriented right-side up, and thus, the third fins 690C extend vertically upward relative to the walls of the third cage 622C. The fourth cage 622D, which is arranged belly-to-belly with the third cage 622C, includes a fourth riding heat sink 688D having fourth fins 690D arranged in the second configuration, much like the second fins 690B of the second cage 622B. The fourth cage 622D is oriented upside down, and thus, the fourth fins 690D extend vertically downward relative to the walls of the fourth cage 622D. The fourth fins 690D, which are arranged in the second configuration, are laterally offset from the first fins 690A and the third fins 690C, which are arranged in the first configuration. The fourth fins 690D are laterally aligned with the second fins 690B, which are also arranged in the second configuration.

The staggered arrangement of the second and third fins 690B, 690C enables the second and third riding heat sinks 688B, 688C to nest with interleaving fins. As shown in FIG. 6, the second fins 690B arranged in the second configuration and the third fins 690C arranged in the first configuration are nested. In this example, the second and third fins 690B, 690C are nested in that they overlap one another along the Z-direction, or rather, along the stack direction. Moreover, the second and third fins 690B, 690C are interleaved. In this example, the second and third fins 690B, 690C alternate along the Y-direction. Other interleaving patterns are contemplated, such as a two-by-two interleaving pattern (wherein two fins from one riding heat sink are arranged adjacent to one another, two fins from the other riding heat sink are arranged adjacent to one another and to the other two fins, etc.), a three-by-three interleaving pattern, etc.

Advantageously, such a nested fin arrangement can allow for the cage assembly 620 to have a vertically compact design and also allows for the second and third cages 622B, 622C to share one or more drain holes 664 defined by a PCB 616 arranged rearward of the cage assembly 620. This can reduce the number of holes needed in the PCB, which can reduce fabrication time of the VLC system and can provide more space for electrical traces and other components on the PCB. The drain holes 664 can each be aligned, at least in part, with the nested riding heat sink arrangement as depicted in FIG. 6, e.g., along the Z-direction and the Y-direction, or stated another way, along a primary airflow direction. In FIG. 6, the drain holes 664 associated with the nested second and third riding heat sinks 688B, 688C are arranged in three (3) staggered rows. However, in other examples, other arrangements are contemplated.

The features illustrated in FIG. 6 and described in the accompanying text can be combined with any of the features described herein, such as the splayed layout of cages, corresponding PCB hole layouts, cage venting features, etc.

In one or more further examples, a VLC system can include a cage assembly with at least a first cage and a second cage each having integrated heat sinks as well as external riding heat sinks with fin arrays. The fin arrays can be staggered, or rather, the fins of the fin arrays can be offset with respect to one another. The first and second cages can be arranged so that the riding heat sinks nest with interleaving fins and so that a drain hole defined by a PCB arranged at a back of the cages is common to each of the riding heat sinks and each of the integrated heat sinks. An example is provided below.

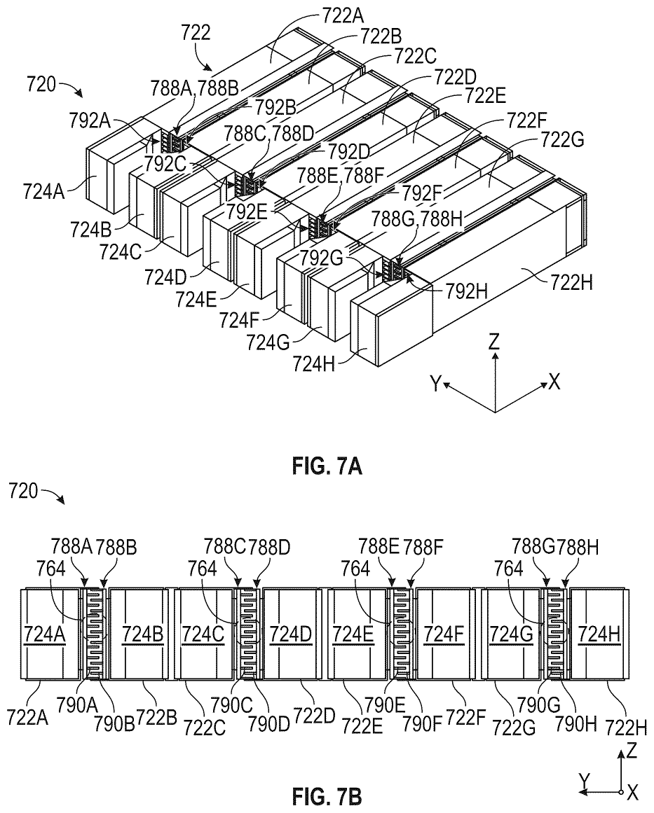

FIGS. 7A and 7B depict a perspective view and a front view of a cage assembly 720 for a VLC system, according to one or more embodiments of the present disclosure. As shown, the cage assembly 720 includes a plurality of cages 722, including a first cage 722A, a second cage 722B, a third cage 722C, a fourth cage 722D, a fifth cage 722E, a sixth cage 722F, a seventh cage 722G, and an eighth cage 722H (collectively the cages 722). The cages 722 are horizontally stacked in this example. The cages 722 can each receive an optical module. As illustrated in FIGS. 7A and 7B, the first cage 722A can receive a first optical module 724A, the second cage 722B can receive a second optical module 724B, the third cage 722C can receive a third optical module 724C, the fourth cage 722D can receive a fourth optical module 724D, the fifth cage 722E can receive a fifth optical module 724E, the sixth cage 722F can receive a sixth optical module 724F, the seventh cage 722G can receive a seventh optical module 724G, and the eighth cage 722H can receive an eighth optical module 724H. The second and third cages 722B, 722C are arranged belly-to-belly, the fourth and fifth cages 722D, 722E are arranged belly-to-belly, and the sixth and seventh cages 722F, 722G are arranged belly-to-belly. The first and eighth cages 722A, 722H, are arranged at opposing ends of the cage assembly 720.

Each one of the cages 722 includes a riding heat sink and an integrated heat sink. As depicted in FIGS. 7A and 7B, the first cage 722A includes a first riding heat sink 788A having first fins 790A arranged in a first configuration. The first cage 722A also includes a first integrated heat sink 792A. The second cage 722B includes a second riding heat sink 788B having second fins 790B arranged in a second configuration. The second cage 722B also includes a second integrated heat sink 792B. The second fins 790B, which are arranged in the second configuration, are vertically offset from the first fins 790A, which are arranged in the first configuration. The first and second riding heat sinks 788A, 788B are arranged between the first and second integrated heat sinks 792A, 792B, e.g., along the Y-direction.

The staggered arrangement of the first and second fins 790A, 790B enables the first and second riding heat sinks 788A, 788B to nest with interleaving fins. In this example, the first and second fins 790A, 790B are nested in that they overlap one another along the Y-direction, or rather, along the stack direction. Moreover, the first and second fins 790A, 790B are interleaved. Advantageously, such a nested fin arrangement can allow for the cage assembly 720 to have a laterally compact design and also allows for the first and second cages 722A, 722B to share one or more drain holes 764 defined by a PCB arranged rearward of the cage assembly 720. The drain holes 764 can be common to, or shared by, the nested first and second riding heat sinks 788A, 788B as well as the first and second integrated heat sinks 792A, 792B. This can reduce the number of holes needed in the PCB, which can reduce fabrication time of the VLC system and can provide more space for electrical traces and other components on the PCB.

The third cage 722C includes a third riding heat sink 788C having third fins 790C arranged in the first configuration. The third cage 722C also includes a third integrated heat sink 792C. The fourth cage 722D includes a fourth riding heat sink 788D having fourth fins 790D arranged in the second configuration. The fourth cage 722D also includes a fourth integrated heat sink 792D. The fifth cage 722E includes a fifth riding heat sink 788E having fifth fins 790E arranged in the first configuration. The fifth cage 722E also includes a fifth integrated heat sink 792E. The sixth cage 722F includes a sixth riding heat sink 788F having sixth fins 790F arranged in the second configuration. The sixth cage 722F also includes a sixth integrated heat sink 792F. The seventh cage 722G includes a seventh riding heat sink 788G having seventh fins 790G arranged in the first configuration. The seventh cage 722G also includes a seventh integrated heat sink 792G. Finally, the eighth cage 722H includes an eighth riding heat sink 788H having eighth fins 790H arranged in the second configuration. The eighth cage 722H also includes an eighth integrated heat sink 792F.

The staggered arrangement of the third and fourth fins 790C, 790D enables the third and fourth riding heat sinks 788C, 788D to nest with interleaving fins. The staggered arrangement of the fifth and sixth fins 790E, 790F enables the fifth and sixth riding heat sinks 788E, 788F to nest with interleaving fins. The staggered arrangement of the seventh and eighth fins 790G, 790H enables the seventh and eighth riding heat sinks 788G, 788H to nest with interleaving fins. Accordingly, in this example, four (4) drain holes 764 defined by the PCB can support eight (8) cages 722.

The features illustrated in FIG. 7 and described in the accompanying text can be combined with any of the features described herein, such as the splayed layout of cages, corresponding PCB hole layouts, cage venting features, etc.

In one or more further examples, a VLC system can include a cage assembly with at least a first cage and a second cage arranged in a back-to-back arrangement, with the first and second cages each having an integrated heat sink as well as an external riding heat sink. The riding heat sinks can include fin arrays that are staggered, or rather, the fins of the fin arrays can be offset with respect to one another. The first and second cages can be arranged so that the riding heat sinks nest with interleaving fins and so that one or more drain holes defined by a PCB arranged at a back of the cages is common to each of the riding heat sinks and each of the integrated heat sinks. An example is provided below.

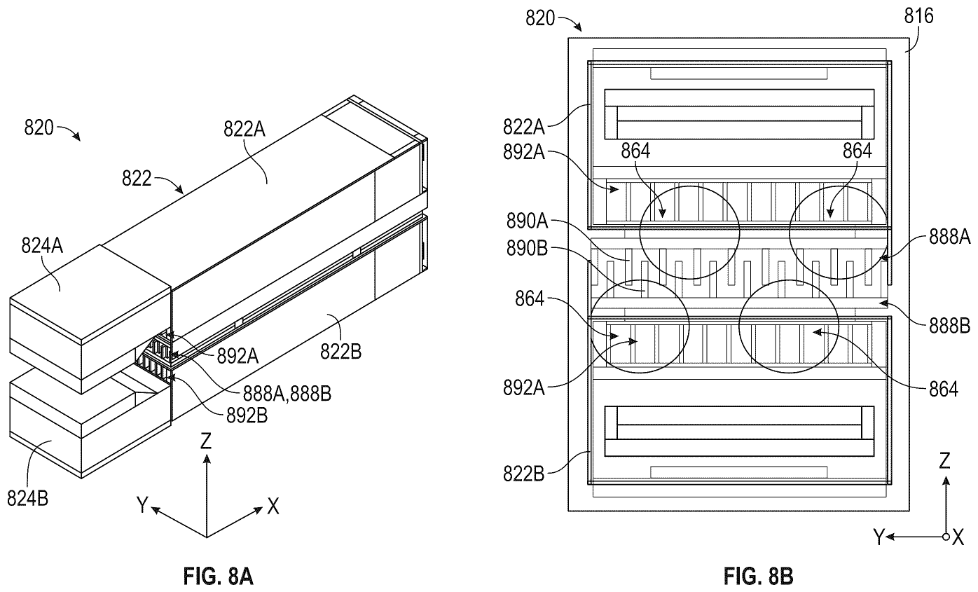

FIGS. 8A and 8B depict a perspective view and a front view of a cage assembly 820 for a VLC system, according to one or more embodiments of the present disclosure. As shown, the cage assembly 820 includes a plurality of cages 822, including a first cage 822A and a second cage 822B (collectively the cages 822). The cages 822 are vertically stacked in this example. The cages 822 can each receive an optical module. As illustrated in FIG. 8A, the first cage 822A can receive a first optical module 824A and the second cage 822B can receive a second optical module 824B. The first and second cages 822A, 822B are arranged in a back-to-back configuration.

Each one of the cages 822 includes a riding heat sink and an integrated heat sink. As depicted in FIGS. 8A and 8B, the first cage 822A includes a first riding heat sink 888A having first fins 890A arranged in a first configuration. The first cage 822A also includes a first integrated heat sink 892A. The second cage 822B includes a second riding heat sink 888B having second fins 890B arranged in a second configuration. The second cage 822B also includes a second integrated heat sink 892B. The second fins 890B, which are arranged in the second configuration, are laterally offset from the first fins 890A, which are arranged in the first configuration. The first and second riding heat sinks 888A, 888B are arranged between the first and second integrated heat sinks 892A, 892B, e.g., along the Z-direction.

The staggered arrangement of the first and second fins 890A, 890B enables the first and second riding heat sinks 888A, 888B to nest with interleaving fins. In this example, the first and second fins 890A, 890B are nested in that they overlap one another along the Z-direction, or rather, along the stack direction. Moreover, the first and second fins 890A, 890B are interleaved. Advantageously, such a nested fin arrangement can allow for the cage assembly 820 to have a vertically compact design and also allows for the first and second cages 822A, 822B to share one or more drain holes 864 defined by a PCB 816 arranged rearward of the cage assembly 820. The drain holes 864 can be common to, or shared by, the nested first and second riding heat sinks 888A, 888B as well as the first and second integrated heat sinks 892A, 892B. This can reduce the number of holes needed in the PCB 816, which can reduce fabrication time of the VLC system and can provide more space for electrical traces and other components on the PCB 816. The drain holes 864 can each be aligned, at least in part, with the first riding heat sink 888A, the second riding heat sink 888B, the first integrated heat sink 892A, or the second integrated heat sink 892B, or some combination thereof, as depicted in FIG. 8B, e.g., along the Z-direction and the Y-direction, or stated another way, along a primary airflow direction. In FIG. 8B, the drain holes 864 are arranged in two (2) staggered rows. However, in other examples, other arrangements are contemplated.

The features illustrated in FIG. 8 and described in the accompanying text can be combined with any of the features described herein, such as the splayed layout of cages, corresponding PCB hole layouts, cage venting features, etc.

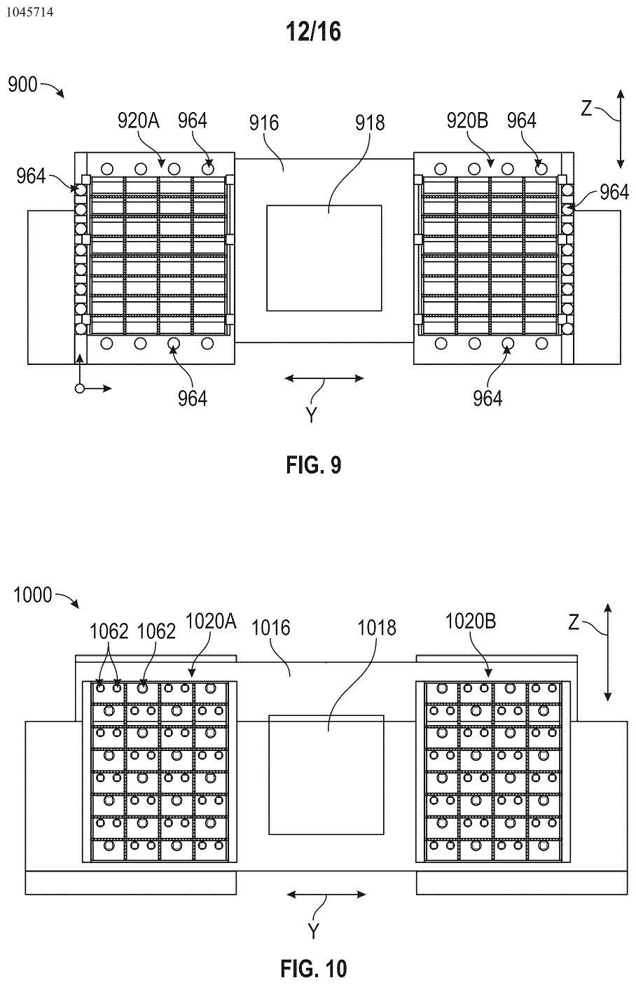

FIG. 9 depicts a front view of an assembly 900 for a VLC system. The assembly 900 can be implemented in the VLC system 100 of FIG. 1, for example. The assembly 900 includes a vertically-oriented PCB, or PCB 916, a vertically-oriented IC, or IC 918, and first and second cage assemblies 920A, 920B having first and second cages. The IC 918 is mounted to a forward face of the PCB 916. The IC 918 can be an ASIC, for example. The first cage assembly 920A and the second cage assembly 920B are disposed on opposite sides of the IC 918 and can be symmetrically arranged with respect to a central plane. In one or more examples, the PCB 916 can define a drain hole 964 at the top and bottom of each column and at an outer end or outboard position of each of the rows, e.g., as shown in FIG. 9. Such an arrangement of drain holes 964 can facilitate airflow to the rear side of the PCB 916.

FIG. 10 depicts a front view of an assembly 1000 for a VLC system. The assembly 1000 can be implemented in the VLC system 100 of FIG. 1, for example. The assembly 1000 includes a vertically-oriented PCB, or PCB 1016, a vertically-oriented IC, or IC 1018, and first and second cage assemblies 1020A, 1020B having first and second cages, which are arranged in a grid layout. The IC 1018 is mounted to a forward face of the PCB 1016. The IC 1018 can be an ASIC, for example. The first cage assembly 1020A and the second cage assembly 1020B are disposed on opposite sides of the IC 1018 and can be symmetrically arranged with respect to a central plane.

In one or more examples, the PCB 1016 can define the cage holes so that, for a given row of cage holes, the cage holes alternate between pairs of small cage holes and large cage holes. In the depicted example of FIG. 10, the PCB 1016 defines cage holes 1062 so that one cage of a row is aligned with a large cage hole and an adjacent cage of the row is aligned with a pair of small cage holes, wherein the large cage hole has a larger diameter than both of the small cage holes. This pattern can continue across the row. Moreover, this pattern can continue for other rows, and the pattern can be staggered from one row to the next, e.g., as shown in FIG. 10.

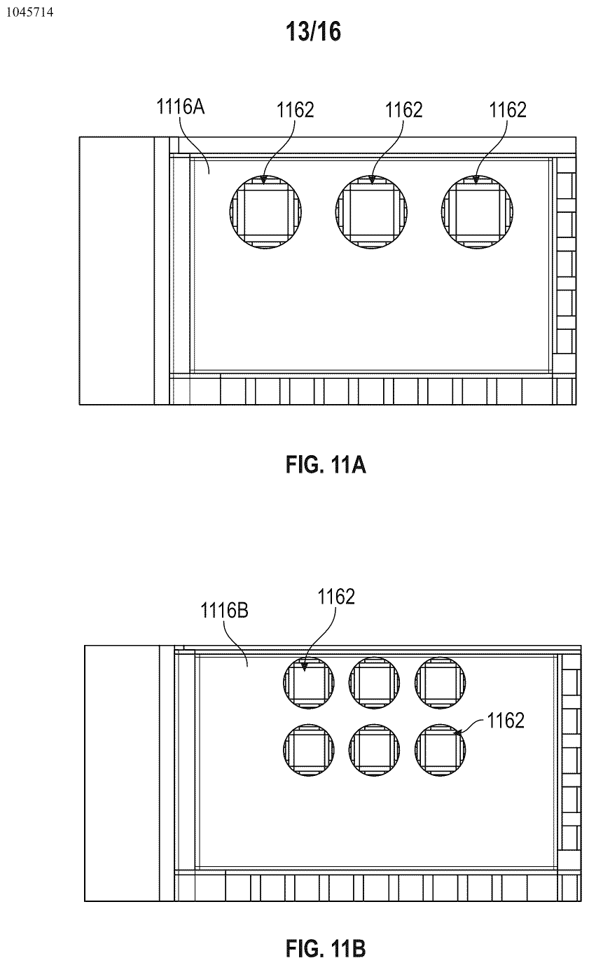

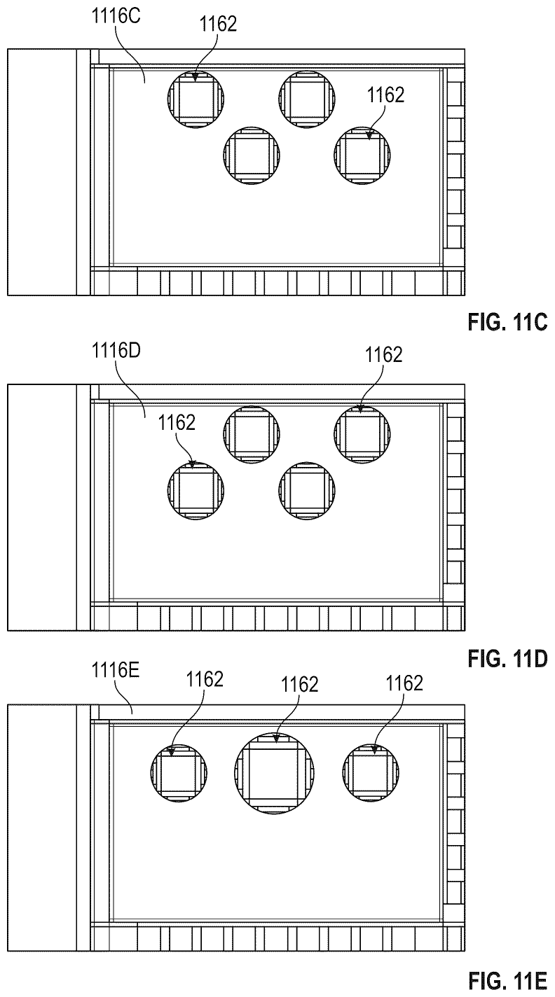

FIGS. 11A, 11B, 11C, 11D, and 11E depict various PCB cage hole arrangements that can be implemented in a VLC system, according to one or more embodiments of the present disclosure.

FIG. 11A depicts a PCB 1116A defining a PCB cage hole pattern associated with a cage of a cage assembly. In FIG. 11A, the PCB 1116A defines a cluster of cage holes, wherein the cage holes 1162 are arranged in a row and have a same diameter. Three (3) cage holes 1162 are depicted in FIG. 11A.

FIG. 11B depicts a PCB 1116B defining a PCB cage hole pattern associated with a cage of a cage assembly. In FIG. 11B, the PCB 1116B defines a cluster of cage holes, wherein the cage holes 1162 are arranged in two (2) rows, have a same diameter, and are not staggered. Six (6) cage holes 1162 are depicted in FIG. 11B.

FIG. 11C depicts a PCB 1116C defining a PCB cage hole pattern associated with a cage of a cage assembly. In FIG. 11C, the PCB 1116C defines a cluster of cage holes, wherein the cage holes 1162 are arranged in two (2) rows, have a same diameter, and are staggered from one row to the next, with the outermost cage hole of the top row being arranged further away from an IC (not pictured) mounted to the PCB 1116C than the outermost cage hole of the bottom row. Six (6) cage holes 1162 are depicted in FIG. 11C.

FIG. 11D depicts a PCB 1116D defining a PCB cage hole pattern associated with a cage of a cage assembly. In FIG. 11D, the PCB 1116D defines a cluster of cage holes, wherein the cage holes 1162 are arranged in two (2) rows, have a same diameter, and are staggered from one row to the next, with the outermost cage hole of the bottom row being arranged further away from an IC (not pictured) mounted to the PCB 1116D than the outermost cage hole of the top row. Six (6) cage holes 1162 are depicted in FIG. 11D.

FIG. 11E depicts a PCB 1116E defining a PCB cage hole pattern associated with a cage of a cage assembly. In FIG. 11E, the PCB 1116E defines a cluster of cage holes, wherein the cage holes 1162 are arranged in a row with the cage hole pattern being small-large-small. Stated differently, the pattern includes a large cage hole flanked on both sides by small cage holes, with the small cage holes having smaller diameters than the large cage hole. Three (3) cage holes 1162 are depicted in FIG. 11E.

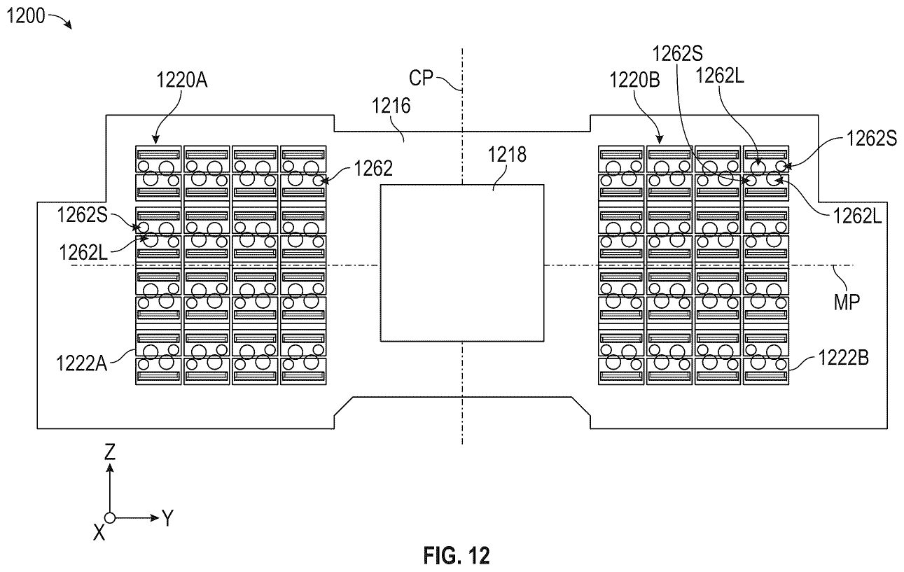

FIG. 12 is a front view of an assembly 1200 for a VLC system, according to one or more embodiments of the present disclosure. The assembly 1200 can be implemented in the VLC system 100 of FIG. 1, for example. The assembly 1200 includes a vertically-oriented PCB, or PCB 1216, a vertically-oriented IC, or IC 1218, and first and second cage assemblies 1220A, 1220B having first and second cages 1222A, 1222B, which are arranged in a grid layout. The IC 1218 is mounted to a forward face of the PCB 1216. The IC 1218 can be an ASIC, for example. The first cage assembly 1220A and the second cage assembly 1220B are disposed on opposite sides of the IC 1218 and can be symmetrically arranged with respect to a central plane CP. The first cages 1222A of the first cage assembly 1220A are arranged above and below a mid-plane MP in upper and lower sets, and likewise, the second cages 1222B of the second cage assembly 1220B are arranged above and below the mid-plane MP in upper and lower sets.

In one or more examples, such as in FIG. 12, at least some of the first cages 1222A can be arranged in a back-to-back configuration so that cage holes 1262 defined by the PCB 1216 can be shared between cages arranged back-to-back. For instance, the first cages 1222A of the top row of the first cage assembly 1220A can be arranged back-to-back with respective first cages 1222A of the second most top row of the first cage assembly 1220A. A top row of cage holes 1262 can be defined by the PCB 1216 such that they are shared by the top row and the second most top row of the first cages 1222A. Three other rows of cage holes 1262 can be shared by other rows of back-to-back configured first cages 1222A as shown in FIG. 12. The second cages 1222B and cage holes 1262 can be similarly arranged on the other side of the central plane CP. In the example of FIG. 12, the first cages 1222A and the second cages 1222B have integrated heatsinks but do not have riding heatsinks. While the first cages 1222A of the first cage assembly 1220A are arranged in a 4×8 array (four columns by eight rows), it will be appreciated that the first cage assembly 1220A can have other suitable cage configurations with at least one back-to-back pair of cages. Other example cage configurations can include quad 8×1, quad 2×4, dual 8×2, dual 4×4, eight 2×1, eight 1×2, etc. The second cage assembly 1220B can likewise have different cage configurations in other examples.

In one or more examples, the PCB 1216 can define the cage holes 1262 so that, for each pair of back-to-back configured cages, the cage holes 1262 are arranged in a staggered arrangement, e.g., such that they overlap at least along the Z-direction, with the cage holes arranged in a pattern having the following sequence: small cage hole 1262S, large cage hole 1262L, large cage hole 1262L, and then small cage hole 1262S, e.g., along the Y-direction, with this pattern repeating along a given row from one pair of back-to-back configured cages to the next pair. The large cage holes 1262L can be aligned with both cages of a pair of back-to-back configured cages along the primary airflow direction (e.g., the X-direction in FIG. 12) and the small cage holes 1262S can be aligned with one but not the other cage of the pair along the primary airflow direction, e.g., as illustrated in FIG. 12. In at least one example, the small cage hole 1262S can overlap with their nearest neighbor large cage hole 1262L, e.g., along the Y-direction. In this regard, for a given pair of back-to-back configured cages, the cage holes shared by the given pair can be staggered vertically and laterally. The large cage holes 1262L can have larger diameters than the small cage holes 1262S, and can be at least twenty-five percent (25%) greater than the small cage holes 1262S, for example. The patterns of the cage holes 1662 of the upper set of cages of the first cage assembly 1220A can be mirrored in the lower set of cages of the first cage assembly 1220A. The patterns of cage holes associated with the first cage assembly 1220A can be mirrored with respect to the second cage assembly 1220B, as depicted in FIG. 12.

The architecture of the assembly 1200 of FIG. 12 can advantageously reduce the number of cage hole rows for a given number of cage rows, which can provide additional space for electrical trace routing. Also, mirroring the cage holes along the mid-plane MP can beneficially provide symmetrical upper/lower pathways for electrical trace routing on the PCB 1216, e.g., from the cages to the IC 1218. Mirroring the cage holes along the central plane CP can provide symmetrical right/left pathways for electrical trace routing on the PCB 1216. Moreover, due to the lower number of cage hole rows, fabrication time creating the holes in the PCB 1216 can be reduced, among other benefits.

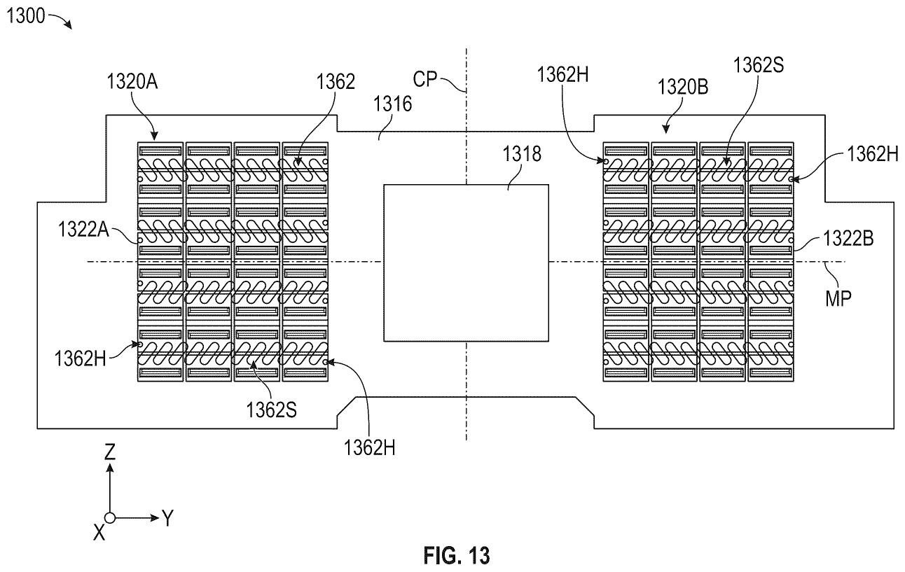

FIG. 13 is a front view of an assembly 1300 for a VLC system, according to one or more embodiments of the present disclosure. The assembly 1300 can be implemented in the VLC system 100 of FIG. 1, for example. The assembly 1300 includes a vertically-oriented PCB, or PCB 1316, a vertically-oriented IC, or IC 1318, and first and second cage assemblies 1320A, 1320B having first and second cages 1322A, 1322B, which are arranged in a grid layout. The IC 1318 is mounted to a forward face of the PCB 1316. The IC 1318 can be an ASIC, for example. The first cage assembly 1320A and the second cage assembly 1320B are disposed on opposite sides of the IC 1318 and can be symmetrically arranged with respect to a central plane CP. The first cages 1322A of the first cage assembly 1320A are arranged above and below a mid-plane MP in upper and lower sets, and likewise, the second cages 1322B of the second cage assembly 1320B are arranged above and below the mid-plane MP in upper and lower sets.

In one or more examples, such as in FIG. 13, at least some of the first cages 1322A can be arranged in a back-back configuration so that cage holes 1362 defined by the PCB 1316 can be shared between cages arranged back-to-back. The second cages 1322B and cage holes 1362 can be similarly arranged on the other side of the central plane CP. In the example of FIG. 13, the first cages 1322A and the second cages 1322B have integrated heatsinks but do not have riding heatsinks. While the first cages 1322A of the first cage assembly 1320A are arranged in a 4×8 array (four columns by eight rows), it will be appreciated that the first cage assembly 1320A can have other suitable cage configurations with at least one back-to-back pair of cages. Other example cage configurations can include quad 8×1, quad 2×4, dual 8×2, dual 4×4, eight 2×1, eight 1×2, etc. The second cage assembly 1320B can likewise have different cage configurations in other examples.

In one or more examples, the PCB 1316 can define the cage holes 1362 so that, for at least one row of cages, the cage holes 1362 are arranged with angled oblong slots 1362S with two small round holes 1362H on opposing sides of the angled oblong slots 1362S, which can facilitate even air flow distribution. The angled oblong slots 1362S can be angled with respect to the Z-direction and the Y-direction, for example, such as at forty-five degrees (45°) with respect to the Z-direction. For a given row of cage holes 1362, the angled oblong slots 1362S can be arranged to align with both cages of a pair of back-to-back configured cages along the primary airflow direction (e.g., the X-direction in FIG. 13). In one or more examples, for the upper set of cages of the first cage assembly 1220A, the top ends of the angled oblong slots 1362S can be arranged further away from the IC 1318 than their respective bottom ends, e.g., along the Y-direction. For the lower set of cages of the first cage assembly 1220A, the top ends of the angled oblong slots 1362S can be arranged closer to the IC 1318 than their respective bottom ends, e.g., along the Y-direction. In this regard, the angled oblong slots 1362S can be mirrored along the mid-plane MP. The small round holes 1362H can likewise be mirrored along the mid-plane MP. Moreover, the angled oblong slots 1362S and small round holes 1362H can be mirrored along the central plane CP, e.g., so that the cage holes 1362 associated with the first cage assembly 1320A mirror the cage holes 1362 associated with the second cage assembly 1320B, e.g., as shown in FIG. 13.

The architecture of the assembly 1300 of FIG. 13 can advantageously reduce the number of cage hole rows for a given set cage rows, which can provide additional space for electrical trace routing. Also, mirroring the cage holes 1362 along the mid-plane MP can beneficially provide symmetrical upper/lower pathways for electrical trace routing on the PCB 1316, e.g., from the cages to the IC 1318. Mirroring the cage holes 1362 along the central plane CP can provide symmetrical right/left pathways for electrical trace routing on the PCB 1316. Moreover, with the reduced number of cage hole rows, fabrication time creating the holes in the PCB 1316 can be reduced. Also, the angled oblong slots 1362S can provide primary airflow openings through the PCB 1316 that uniquely direct the flow through the PCB 1316 while the angled spaces on the PCB 1316 between the angled oblong slots 1362S can allow for angled electrical traces that efficiently traverse between the cages and the IC 1318 along the PCB 1316. The small round holes 1362H on opposing sides of the angled oblong slots 1362S can facilitate even air flow distribution.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. A system, comprising:
a vertically-oriented printed circuit board (PCB);
a vertically-oriented integrated circuit (IC) mounted to the PCB; and
a cage assembly having cages arranged in a splayed layout so that the cages angularly fan out with respect to the IC.

2. The system of claim 1, wherein the system defines a vertical direction, a longitudinal direction, and a lateral direction mutually perpendicular to one another, and wherein the cages are arranged in the splayed layout so that a width axis of each one of the cages is angled with respect to the lateral direction.

3. The system of claim 2, wherein the cages are arranged in the splayed layout in at least one column, and wherein angles of the cages of the at least one column, with respect to the lateral direction, increase in increments from one row of cages of the at least one column to a next row.

4. The system of claim 2, wherein the cages are arranged in the splayed layout in at least two columns, including a first column and a second column arranged outward of the first column with respect to the IC, and wherein angles of the cages of the first column, with respect to the lateral direction, increase in first increments from one row of cages of the first column to a next row, and wherein angles of the cages of the second column, with respect to the lateral direction, increase in second increments from one row of cages of the second column to a next row, and wherein the second increments are greater than the first increments.

5. The system of claim 1, wherein the cages are arranged in the splayed layout so that a first set of the cages is arranged above a fan out plane and a second set of the cages is arranged below the fan out plane, and wherein the cages of the first set are angled with a positive angle with respect to the fan out plane and the cages of the second set are angled with a negative angle with respect to the fan out plane.

6. The system of claim 5, wherein each one of the cages has an inner end and an outer end, and wherein the cages are arranged in the splayed layout so that, for a given cage of the cages, the inner end of the given cage is arranged closer to the fan out plane than the outer end of the given cage.

7. The system of claim 1, wherein the cages are arranged in the splayed layout so that flow channels defined between rows of the cages progressively increase in cross-sectional area as the flow channels extend away from the IC.

8. The system of claim 1, wherein the vertically-oriented PCB defines a plurality of holes, including cage holes and drain holes, with the cage holes being aligned with respective ones of the cages along a primary airflow direction and the drain holes not being aligned with the cages along the primary airflow direction.

9. The system of claim 8, wherein the vertically-oriented PCB defines the cage holes so that, for at least one row of the plurality of holes, the cage holes of the at least one row decrease in size the closer the cage holes of the at least one row are to a drain hole of the drain holes that is associated with the at least one row.

10. The system of claim 8, wherein the vertically-oriented PCB defines the cage holes so that, for at least one row of the plurality of holes, the cage holes of the at least one row alternate between pairs of small cage holes and large cage holes, with small cage holes of the pairs of small cage holes being relatively smaller in diameter than the large cage holes.

11. The system of claim 10, wherein the vertically-oriented PCB defines the cage holes so that, for a second row of the plurality of holes that is positioned adjacent the at least one row of the plurality of holes, the cage holes of the second row alternate between pairs of small cage holes and large cage holes, and wherein the alternating pattern of the at least one row is staggered with respect to the alternating pattern of the second row.

12. The system of claim 8, wherein the cages include cage vents at their respective rear portions that allow air to escape the cages and flow to the drain holes.

13. The system of claim 12, wherein the cages each include a top wall, a bottom wall, and opposing sidewalls, and wherein a cage vent of at least one cage of the cages is defined by the top wall, the bottom wall, and the opposing sidewalls of the at least one cage.

14. The system of claim 12, wherein air escaping the cages through the cage vents flows laterally to the drain holes by way of flow channels defined between the cages.

15. A system, comprising:
a vertically-oriented printed circuit board (PCB) defining cage holes and drain holes;
a vertically-oriented integrated circuit (IC) mounted to the PCB; and
a cage assembly having cages arranged in a splayed layout so that the cages angularly fan out with respect to the IC and define flow channels therebetween, wherein the cages align with the cage holes along a primary airflow direction and have cage vents that allow air to escape the cages and flow by way of the flow channels to the drain holes.

16. The system of claim 15, wherein the cages are arranged in the splayed layout so that flow channels defined between rows of the cages progressively increase in cross-sectional area as the flow channels extend away from the IC.

17. A system, comprising:
a vertically-oriented printed circuit board (PCB) defining a slot and a plurality of cage holes;
a vertically-oriented integrated circuit (IC) mounted to the PCB above the slot; and
a cage assembly having a cage frame supporting a plurality of cages and having a front and a back spaced from one another along a first direction, the cage frame defines slots each having a long axis extending along the first direction and aligned with walls of the cages.

18. The system of claim 17, wherein the cage frame has a top frame wall and a side frame wall, and wherein the top frame wall, the side frame wall, or both, define at least one of the slots.

19. The system of claim 17, wherein the cage frame defines at least one frame vent arranged at the back of, and aligned with, at least one of the plurality of cages.

20. The system of claim 17, wherein the cage assembly comprises:
a forward stiffener flange arranged to couple with a forward faceplate of a chassis of a system;
a plurality of tabs arranged at the back and being vertically spaced from one another, and wherein the tabs are arranged to couple with a vertically-oriented printed circuit board; and
standoff bars extending between and coupling the forward stiffener flange and respective ones of the plurality of tabs.
